(19) United States
(12) Patent Application Publication
(10) Pub. No.: US 2026/0218010 A1
(43) Pub. Date: Jul. 30, 2026

(54) PHOSPHINIMIDE COMPLEXES AS DEPOSITION PRECURSORS FOR THIN LAYERS

(71) Applicant: ASM IP Holding B.V., Almere (NL)

(72) Inventors: Patricio Eduardo Romero, Boutersem (BE); Charles Dezelah, Helsinki (FI)

(21) Appl. No.: 19/460,480

(22) Filed: Jan. 27, 2026

Related U.S. Application Data
(60) Provisional application No. 63/751,575, filed on Jan. 30, 2025.

(51) Int. Cl. C09D 183/16; C23C 16/455; H01J 37/32; H10P 14/60; H10P 14/68

(52) U.S. Cl. CPC C09D 183/16; C23C 16/45527; C23C 16/45544; C23C 16/45553; H01J 37/3244; H10P 14/6339; H10P 14/68; H01J 2237/332

(57) ABSTRACT

A composition for forming a layer on a semiconductor substrate is provided. The composition comprising a deposition precursor comprising a central atom or ion (M) and at least one phosphinimide ligand (L¹). Also provided is a method and a system for forming a layer on a semiconductor substrate using the composition.

### CROSS-REFERENCE TO RELATED APPLICATIONS

This application claims priority to U.S. Provisional Patent Application Ser. No. 63/751,575 filed Jan. 30, 2025 titled PHOSPHINIMIDE COMPLEXES AS DEPOSITION PRECURSORS FOR THIN LAYERS, the disclosure of which is hereby incorporated by reference in its entirety.

### FIELD OF INVENTION

The present disclosure generally relates to the field of semiconductor devices. More particularly, it relates to methods, precursors, and compositions for forming thin films or layers on a semiconductor substrate, related devices and apparatuses for producing the same.

### BACKGROUND OF THE DISCLOSURE

At present, the selection of atomic layer deposition (ALD) and chemical vapour deposition (CVD) precursors for growth of thin films is restricted to those containing only a few types of ligands, such as Cp, amidinates, beta-diketonates, dialkylamides, alkoxides, alkyls, and so on. The known examples have limitations that make them less than ideal for the growth of desired layers (films). Limitations include a limited (and often insufficient) range of reactivity, halogen contamination, and other types of contamination, oxygen incorporation, low volatility, or low thermal stability and low activation energy decomposition pathways that lead to impurities and high electrical resistivity. These drawbacks make the current chemistry options sub-optimal choices for film growth for many applications. For advanced memory applications in particular, there is a current need to generate increased flux in order to cover very high aspect ratio features, as well as the ability to operate at higher thermal budgets to define the correct crystalline phase. The current palette of precursor is unable to fulfil these conditions and therefore new ligand platforms are needed.

In view of the above, a need exists to provide alternatives for ALD and/or CVD precursors for thin film deposition that are capable of overcoming some of these drawbacks.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In general, the technology disclosed herein relates to the field of semiconductor devices, and more particularly to methods, precursors, and compositions for forming thin films or layers on a semiconductor substrate using a novel deposition precursor that comprises a phosphinimide ligand. The precursor may contain other common ligands in addition to the phosphinimide ligand. Deposition may be in the form of oxides, nitrides, carbides, borides, sulfides, phosphides and the like. These methods and compositions are applicable to the manufacture of semiconductor devices.

The deposition precursors according to the present invention exhibit increased thermal stability, due to a combination of kinetic stabilization and greater electron donation to the metal centre. Accordingly, the deposition precursors according to the present invention have improved reactivity compared to current methods, and also provide improvements in thermal stability, volatility, and ability to access difficult materials such as carbides, borides, and nitrides, which makes their use in compositions, methods and apparatuses for forming layers on semiconductor substrates very advantageous.

In addition, the compositions comprising the deposition precursors according to the present invention have shown an ability of forming layers or films with a very high degree of purity when compared with compositions of the prior art. In particular, the present compositions comprise very low levels of impurities such as halogen containing impurities, or metal containing impurities, compared to precursors that do contain halogen. The present compositions are thus particularly advantageous for forming halide-free layers or films.

A number of benefits of using the deposition precursors according to the invention, relative to existing precursors, include:
1) Phosphinimides are topologically related to alkoxides. The latter are ubiquitous in ALD and CVD chemistry, as they impart good volatility and thermal stability when attached to deposition precursors. Advantageously, such topological similarity can allow their chemical and physical behavior to be predicted and fine-tuned without requiring a complete re-evaluation of the phosphinimide's compatibility with the ALD and/or CVD process.
2) Phosphinimides provide increased thermal stability to complexes, due to resonance delocalization with the metal centre.
3) Phosphinimides provide a large degree of steric tuning, through straightforward variations at the phosphorus atom.
4) They are easily synthesized, inexpensive, and accessible in large scale.
5) Since the atom of the ligand that attaches to the central atom or ion is nitrogen, a high degree of reactivity towards protic reactants can be expected (by analogy to alkylamido ligands).
6) In specific embodiments, the N—P bond could be induced to break, allowing a pathway for readily forming nitride films.

Accordingly, an aspect of the present disclosure relates to a composition for forming a layer on a semiconductor substrate, the composition comprising a deposition precursor comprising:
a central atom or ion (M); and
at least one phosphinimide ligand (L¹).

Another aspect of the present invention relates to a vapor delivery vessel comprising the composition according to aspects described herein, wherein the vapor delivery vessel is constructed and arranged to supply a vapor of the deposition precursor to a reaction chamber of a vapor deposition apparatus.

Yet another aspect of the present invention relates to a vapor deposition apparatus comprising:
a reaction chamber constructed and arranged to hold at least a semiconductor substrate;
a vapor delivery vessel comprising a composition comprising a deposition precursor, wherein the vapor delivery vessel is constructed and arranged to provide a vapor of the deposition precursor;
a precursor distribution and removal system configured to provide the vapor of the deposition precursor from the vapor delivery vessel to the reaction chamber and to remove the vapor of the deposition precursor from the reaction chamber; and
a sequence controller operably connected to the precursor distribution system and removal system, and comprising a memory provided with a program configured to control the flow of the composition comprising the deposition precursor from the vapor delivery vessel to the reaction chamber by activating the precursor distribution and removal system during one or more cycles; whereby, as a result of the cycles, a layer is formed on the semiconductor substrate in the reaction chamber;
   wherein the deposition precursor comprises:
a central atom or ion (M); and
at least one phosphinimide ligand (L¹).

Yet another aspect of the present disclosure relates to a method for forming a layer on a semiconductor substrate, comprising the steps of:
a) providing a semiconductor substrate into a reaction chamber;
b) executing one or more cycles, each cycle comprising:
   a deposition precursor pulse, wherein at least a part of the semiconductor substrate is contacted by a vapor of a composition comprising the deposition precursor by introducing the vapor of a composition comprising the deposition precursor into the reaction chamber;
      wherein the deposition precursor comprises:
a central atom or ion (M); and
at least one phosphinimide ligand (L¹);
   whereby, as a result of the cycle(s), the layer is formed on the semiconductor substrate in the reaction chamber.

Yet another aspect of the present disclosure relates to a semiconductor device structure. The semiconductor device structure according to the present invention comprises a layer formed according to a method disclosed herein above.

In one or more particular embodiments for any of the herein described aspects, the composition of the invention comprises at least one phosphinimide ligand (L¹) having a structure according to formula (I):

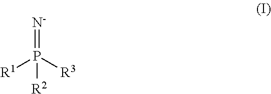

wherein,
R¹ is selected from the group comprising H, an optionally substituted hydrocarbyl group, optionally substituted amino group, and an optionally substituted silyl group;
R² is selected from the group comprising H, an optionally substituted hydrocarbyl group, optionally substituted amino group, and an optionally substituted silyl group;
R³ is selected from the group comprising H, an optionally substituted hydrocarbyl group, an optionally substituted amino group, and an optionally substituted silyl group;
with the proviso that at least one of R¹, R², and R³ is not H.

An overview of various other aspects of the technology of the present disclosure is provided herein below, followed by a detailed description of specific embodiments. It should be understood that the objectives and advantages mentioned above apply equally to the various other aspects and features as disclosed herein.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 schematically illustrates an exemplary embodiment of a method (100) for forming a layer on a semiconductor substrate in accordance with an embodiment of the present disclosure.

FIG. 2 schematically illustrates an exemplary embodiment of an apparatus (600) in accordance with an embodiment of the present disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims. Hence, the description below is to be regarded as illustrative in nature, and not as restrictive.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” the recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). This applies to numerical ranges irrespective of whether they are introduced by the expression “from . . . to . . . ” or the expression “between . . . and . . . ” or another expression. The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, apparatus, systems, or methods that provide “improved” performance (e.g. increased or decreased results, depending on the context). It is to be understood that unless otherwise stated, such “improvement” is a measure of a benefit obtained based on a comparison to devices, structures, apparatus, systems or methods in the prior art. Furthermore, it is to be understood that the degree of improved performance may vary between disclosed embodiments and that no equality or consistency in the amount, degree, or realization of improved performance is to be assumed as universally applicable.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a layer matrix or a main skeleton of a layer.

In the present description, technology is described that relates to a composition, method and apparatus for manufacturing a layer on a semiconductor substrate. The present inventors have surprisingly observed that deposition precursors comprising phosphinimide ligands can be readily used for forming layers on semiconductor substrates. Furthermore, compositions comprising the precursors according to the invention are capable of forming films with a very high degree of purity, which is particularly advantageous for halide-free films. Advantageously, the deposition precursors according to the present description exhibit increased thermal stability, due to a combination of kinetic stabilization and greater electron donation to the metal centre, and are easy to synthesize, allowing for a wide range of materials to be readily accessible of the forming of layers on semiconductor substrates.

Accordingly, one aspect of the present disclosure relates to a composition for forming a layer on a semiconductor substrate, the composition comprising a deposition precursor comprising:
a central atom or ion (M); and
at least one phosphinimide ligand (L¹).

The terms “substrate” or “semiconductor substrate” are used herein interchangeably and can refer to any underlying material or materials that can be used to form, or upon which, a device, a circuit, or a layer (film) can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can comprise a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate.

Examples of suitable substrates include wafers, such as silicon, silica, glass, or GaAs wafers. The wafer may have one or more layers of differing materials deposited on it from a previous manufacturing step. For example, the wafers may include silicon layers (crystalline, amorphous, porous, etc.), silicon oxide layers, silicon nitride layers, silicon oxy nitride layers, carbon doped silicon oxide (SiCOH) layers, or combinations thereof. Additionally, the wafers may include copper layers or noble metal layers (e.g. platinum, palladium, rhodium, or gold). The wafers may include barrier layers, such as manganese, manganese oxide, etc. Plastic layers, such as poly(3,4-ethylenedioxythiophene)poly (styrenesulfonate) may also be used. The layers may be planar or patterned.

In particular embodiments, the substrate may comprise a material such as crystalline silicon, silicon oxide, strained silicon, silicon germanium, sapphire, doped or undoped polysilicon, doped or undoped silicon, patterned or non-patterned silicon on insulator (SOI), carbon doped silicon oxides, silicon carbide, silicon nitride, germanium, gallium arsenide, gallium nitride, glass, or combinations thereof (as the bulk semiconductor material).

A “film” or “layer” as used herein interchangeably refers to a material extending in a direction perpendicular to a thickness direction to cover an entire target or concerned surface, or simply a layer covering a target or concerned surface. In particular embodiments, a film or layer refers to a structure having a certain thickness formed on a surface or a synonym of film or a non-film structure. A layer can encompass a continuous or non-continuous structure or material, such as material deposited according to the present technology. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers.

For example, a film and/or layer can include two-dimensional materials, three-dimensional materials, nanoparticles, or even partial or full molecular layers or partial or full atomic layers or clusters of atoms and/or molecules, or layers consisting of isolated atoms and/or molecules. A film or layer may comprise material or a layer with pinholes, which may be continuous or non-continuous.

As used herein, the term “deposition precursor” refers to a chemical compound, molecule, or composition that contains at least one element intended to be incorporated into a material layer on a substrate during a deposition process. The deposition precursor is characterized by its ability to undergo chemical or physical transformations, such as decomposition, reaction with a co-reactant, or adsorption, under conditions suitable for processes such as atomic layer deposition (ALD), chemical vapor deposition (CVD), or related techniques. In the present context, the deposition precursor comprises a central atom or ion and one or more phosphinimide ligands.

As used herein, the term “central atom or ion” refers to the core atom or ion within a chemical compound or complex (present in the deposition precursor) to which one or more ligands are bound. It should be clear that the present invention is not particularly limited to a specific core atom or ion, as the selection may depend on the material intended to be deposited onto a substrate during a deposition process. For instance, the central atom or ion may include an alkali metal, alkaline earth metal, transition metal, lanthanide, metalloid, or combinations thereof.

In some embodiments the central atom or ion (M) is selected from the group comprising Al, Ga, In, B, Si, Ge, a lanthanide, a transition metal, and a metalloid.

As used herein, “lanthanide” refers to the series of chemical elements comprising the chemical elements with atomic number 57-71, from lanthanum through lutetium. The lanthanides may be selected from: La, Ce, Pr, Nd, Pm, Sm, Eu, Gd, Tb, Dy, Ho, Er, Tm, Yb, and Lu.

As used herein “transition metal” refers to the chemical elements in the d-block of the periodic table, i.e. groups 3 to 12.

As used herein, “metalloid” refers to a chemical element which properties are a mixture of those of metals and nonmetals. Metalloids include the following elements: B, Si, Ge, As, Sb and Te. In some embodiments, a metalloid is selected from the group comprising Si, Ge and B.

In some embodiments, the central atom or ion (M) is selected from the group comprising Al, Ga, In, Si, Ge, B, a rare earth metal, a group 4 metal, a group 5 metal, a group 6 metal.

As used herein, “rare earth metal” refers to the following elements: Sc, Y, La, Ce, Pr, Nd, Pm, Sm, Eu, Gd, Tb, Dy, Ho, Er, Tm, Yb, and Lu. In some embodiments, a rare earth metal is selected from the group comprising Sc, Y, La, Ce, Pr, Nd, Er, Tm, and Lu.

As used herein, “group 4 metal” refers to the following elements: Ti, Zr, Hf, and Rf. In some embodiments, a group 4 metal is selected from the group comprising Ti, Zr, and Hf.

As used herein, “group 5 metal” refers to the following elements: V, Nb, Ta, and Db. In some embodiments, a group 5 metal is selected from the group comprising V, Nb, and Ta.

As used herein, “group 6 metal” refers to the following elements: Cr, Mo, W and Sg. In some embodiments, a group 6 metal is selected from the group comprising Cr, Mo, and W.

In some embodiments, the central atom or ion (M) is selected from the group comprising Al, Ga, In, Si, Ge, B, Sc, Y, La, Ce, Pr, Nd, Er, Tm, Lu, Ti, Zr, Hf, V, Nb, Ta, Cr, Mo, and W.

As used herein, a “phosphinimide ligand” or “phosphorane imidato ligand” generally refers to a ligand comprising a phosphorus atom doubly bonded to a nitrogen atom (P═N), where the phosphorus atom is further bonded to one or more substituents. In particular, the present phosphinimide ligand may be represented by the general formula NPR₃⁻, wherein each R group may independently be selected from hydrogen or organic substituents, such as amino groups, hydrocarbyl groups, or silyl groups which may optionally be substituted. Depending on its coordination state in the complex comprised in the deposition precursor, the nitrogen atom may carry a negative formal charge or be neutral. In the present context, the phosphinimide ligand may act as electron-donating or π-donating ligand, forming coordinate bonds with the central atom or ion.

In some embodiments, at least one phosphinimide ligand (L¹) has a structure according to formula (I):

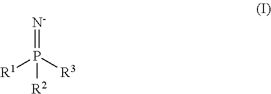

wherein,
R¹ is selected from the group comprising H, an optionally substituted hydrocarbyl group, optionally substituted amino group, and an optionally substituted silyl group;
R² is selected from the group comprising H, an optionally substituted hydrocarbyl group, optionally substituted amino group, and an optionally substituted silyl group;
R³ is selected from the group comprising H, an optionally substituted hydrocarbyl group, an optionally substituted amino group, and an optionally substituted silyl group;
with the proviso that at least one of R¹, R², and R³ is not H.

Reference throughout this specification to substituents is meant to indicate that one or more hydrogen atoms on the atom indicated in the expression using “substituted” is replaced, provided that the indicated atom's normal valence is not exceeded, and that the substitution results in a chemically stable compound, i.e., a compound that is sufficiently robust to survive isolation from a reaction mixture.

Suitable substituents for the hydrocarbyl group, amino group, and/or silyl group as defined herein include alkyl, alkenyl, alkynyl, aryl, or alkoxy groups.

The term “hydrocarbyl group” refers to a chemical functional group that is derived from a hydrocarbon less one hydrogen. Hydrocarbyl groups according to the invention include, but are not limited to, alkyl groups, cycloalkyl groups, cycloalkenyl groups, alkenyl groups, alkynyl groups, and aryl groups.

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₁₀alkyl”, as a group or part of a group, refers to a hydrocarbyl group of formula —CₙH₂ₙ₊₁ wherein n is a number ranging from 1 to 10. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl, sec-butyl, and t-butyl); pentyl and its isomers, neo-pentyl, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

The term “cycloalkyl”, as a group or part of a group, refers to a cyclic alkyl group, that is a monovalent, saturated, hydrocarbyl group having 1 or more cyclic structure, and comprising from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged and/or joined through one or more spiro atoms. When a subscript is used herein following a carbon atom, the subscript refers to the number of carbon atoms that the named group may contain. For example, the term “C₃₋₁₀cycloalkyl”, a cyclic alkyl group comprising from 3 to 10 carbon atoms. For example, the term “C₃₋₈cycloalkyl”, a cyclic alkyl group comprising from 3 to 8 carbon atoms. For example, the term “C₃₋₆cycloalkyl”, a cyclic alkyl group comprising from 3 to 6 carbon atoms. Examples of C₃₋₁₀cycloalkyl groups include but are not limited to adamantyl, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (1S,4S)-norbornan-2-yl, (1R,4S)-norbornan-2-yl.

The term “cycloalkenyl”, as a group or part of a group, refers to a non-aromatic cyclic alkenyl group, with at least one site (usually 1 to 3, preferably 1) of unsaturation, namely a sp² carbon-sp² carbon double bond; preferably from 5 to 18 carbon atoms, more preferably from 5 to 10 carbon atoms, more preferably from 5 to 6 carbon atoms. Cycloalkenyl includes all unsaturated hydrocarbon groups containing one or more rings, including monocyclic, bicyclic, or tricyclic groups. For example, cycloalkenyl can comprise C₅₋₁₀ monocyclic or C₇₋₁₈ polycyclic hydrocarbon. The further rings may be either fused, bridged and/or joined through one or more spiro atoms. When a subscript is used herein following a carbon atom, the subscript refers to the number of carbon atoms that the named group may contain. For example, the term “C₅₋₁₀cycloalkenyl”, refers to a cyclic alkenyl group comprising from 5 to 10 carbon atoms. For example, the term “C₅₋₈ cycloalkenyl”, refers to a cyclic alkenyl group comprising from 5 to 8 carbon atoms. For example, the term “C₅₋₆cycloalkenyl”, refers to a cyclic alkenyl group comprising from 5 to 6 carbon atoms. Examples include, but are not limited to: cyclopentadienyl (Cp), cyclobutenyl, cyclopentenyl (—C₅H₇), cyclopentenylpropylene, methylcyclohexenylene, and cyclohexenyl (—C₆H₉). The double bond may be in the cis or trans configuration. For the avoidance of doubt, fused systems of a cycloalkenyl ring with a heterocyclic ring are considered as heterocycle irrespective of the ring that is bound to the core structure. Fused systems of a cycloalkenyl ring with an aryl ring are considered as aryl irrespective of the ring that is bound to the core structure. Fused systems of a cycloalkenyl ring with a heteroaryl ring are considered as heteroaryl irrespective of the ring that is bound to the core structure. A “substituted cycloalkenyl” refers to a cycloalkenyl group having one or more substituent(s) (for example 1, 2, or 3 substituent(s), or 1 to 2 substituent(s)), at any available point of attachment. Examples of substituted cycloalkenyl groups include MeCp, Me₂Cp, EtCp, i-PrCp, t-BuCp, and TMSCp.

The term “alkenyl” refers to an unsaturated hydrocarbyl group, which may be linear, or branched, comprising one or more carbon-carbon double bonds. When a subscript is used herein following a carbon atom, the subscript refers to the number of carbon atoms that the named group may contain. For example, the term “C₂₋₁₀alkenyl” refers to an unsaturated hydrocarbyl group, which may be linear, or branched comprising one or more carbon-carbon double bonds and comprising from 2 to 10 carbon atoms. For example, C₂₋₆alkenyl includes all linear or branched alkenyl groups having 2 to 6 carbon atoms. Examples of C₂₋₆alkenyl groups are ethenyl, 2-propenyl, 2-butenyl, 3-butenyl, 2-pentenyl and its isomers, 2-hexenyl and its isomers, 2,4-pentadienyl, and the like.

The term “alkynyl” refers to an unsaturated hydrocarbyl group, which may be linear, or branched, comprising one or more carbon-carbon triple bonds. When a subscript is used herein following a carbon atom, the subscript refers to the number of carbon atoms that the named group may contain. For example, the term “C₂₋₁₀alkynyl” refers to an unsaturated hydrocarbyl group, which may be linear, or branched comprising one or more carbon-carbon triple bonds and comprising from 2 to 10 carbon atoms. For example, C₂₋₆alkynyl includes all linear or branched alkynyl groups having 2 to 6 carbon atoms. Non limiting examples of C₂₋₆alkynyl groups include ethynyl, 2-propynyl, 2-butynyl, 3-butynyl, 2-pentynyl and its chain isomers, 2-hexynyl and its chain isomers, and the like.

The term “aryl”, as a group or part of a group, refers to a polyunsaturated, aromatic hydrocarbyl group having a single ring (i.e. phenyl, cyclopentadienyl) or multiple aromatic rings fused together (e.g. naphthyl), or linked covalently, typically containing 5 to 12, wherein at least one ring is aromatic. The aromatic ring may optionally include one to two additional rings (either cycloalkyl, heterocyclyl or heteroaryl) fused thereto. Examples of suitable aryl include C₅₋₁₀aryl, more preferably C₅₋₈aryl. Non-limiting examples of aryl comprise cyclopentadienyl, phenyl, biphenylyl, biphenylenyl, or 1- or 2-naphthanelyl; 1-, 2-, 3-, 4-, 5-, or 6-tetralinyl (also known as “1,2,3,4-tetrahydronaphthalene); 1-, 2-, 3-, 4-, 5-, 6-, 7-, or 8-azulenyl, 4-, 5-, 6 or 7-indenyl; 4- or 5-indanyl; 5-, 6-, 7-, or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2, or 3 substituent(s), or 1 to 2 substituent(s)), at any available point of attachment. Examples of substituted aryl include phenyl (Ph), MePh, EtPh and the like.

The term “amino group” refers to a group of formula —N(R^{o})(R^{p}) wherein R^{o} and R^{p} are each independently selected from hydrogen, C₁₋₆alkyl, C₂₋₆alkenyl, C₂₋₆alkynyl, C₃₋₁₀cycloalkyl or C₅₋₁₂aryl. Preferably, an amino group is selected from the group comprising —NH₂, mono-C₁₋₆alkylamino, and di-C₁₋₆alkylamino.

The term “mono- or di- —C₁₋₆alkylamino” refers to a group of formula —N(R^{o})(R^{p}) wherein R^{o} and R^{p} are each independently selected from hydrogen, or C₁₋₆alkyl, wherein at least one of R^{o} or R^{p} is C₁₋₆alkyl. Thus, alkylamino includes mono-alkyl amino group (e.g. mono-C₁₋₆ alkylamino group such as methylamino and ethylamino) and di-alkylamino group (e.g. di-C₁₋₆ alkylamino group such as dimethylamino and diethylamino). Non-limiting examples of suitable mono- and di-C₁₋₆alkylamino groups include n-propylamino, isopropylamino, n-butylamino, i-butylamino, sec-butylamino, t-butylamino, pentylamino, n-hexylamino, di-n-propylamino, di-i-propylamino, ethylmethylamino, methyl-n-propylamino, methyl-1-propylamino, n-butylmethylamino, i-butylmethylamino, t-butylmethylamino, ethyl-n-propylamino, ethyl-1-propylamino, n-butylethylamino, i-butylethylamino, t-butylethylamino, di-n-butylamino, di-i-butylamino, methylpentylamino, methylhexylamino, ethylpentylamino, ethylhexylamino, propylpentylamino, propylhexylamino, and the like.

The term “silyl group” refers to a group of formula —Si(R^{o})(R^{p})(R^{q}) wherein R^{o}, R^{p} and R^{q} are each independently selected from hydrogen, C₁₋₆alkyl, C₂₋₆alkenyl, C₂₋₆alkynyl, C₃₋₁₀cycloalkyl or C₅₋₁₂aryl. Preferably, a silyl group is selected from the group comprising —SiH₃, mono-C₁₋₆alkylsilyl, di-C₁₋₆alkylsilyl, and tri-C₁₋₆alkylsilyl.

The term “mono-, di- or tri-C₁₋₆alkylsilyl” refers to a group of formula —Si(R^{o})(R^{p})(R^{q}) wherein R^{o}, R^{p} and R^{q} are each independently selected from hydrogen, or C₁₋₆alkyl, wherein at least one of R^{o}, R^{p} or R^{q} is C₁₋₆alkyl. Thus, mono-C₁₋₆alkylsilyl includes groups such as methylsilyl and ethylsilyl; di-C₁₋₆alkylsilyl includes groups such as dimethylsilyl and diethylsilyl and tri-C₁₋₆ alkylsilyl includes groups such as trimethylsilyl and triethylsilyl. Non-limiting examples of suitable mono-, di- and tri-C₁₋₆alkylsilyl groups include n-propylsilyl, isopropylsilyl, n-butylsilyl, i-butylsilyl, sec-butylsilyl, t-butylsilyl, pentylsilyl, n-hexylsilyl, di-n-propylsilyl, di-i-propylsilyl, ethylmethylsilyl, methyl-n-propylsilyl, methyl-i-propylsilyl, n-butylmethylsilyl, i-butylmethylsilyl, t-butylmethylsilyl, ethyl-n-propylsilyl, ethyl-i-propylsilyl, n-butylethylsilyl, i-butylethylsilyl, t-butylethylsilyl, di-n-butylsilyl, di-i-butylsilyl, methylpentylsilyl, methylhexylsilyl, ethylpentylsilyl, ethylhexylsilyl, propylpentylsilyl, propylhexylsilyl, tri-methylsilyl, tri-ethylsilyl, tri-n-propylsilyl, tri-isopropylsilyl, tri-n-butylsilyl, tri-i-butylsilyl, and the like.

The term “C₁₋₆alkoxy”, as a group or part of a group, refers to a group having the formula —OR^{b} wherein R^{b} is C₁₋₆alkyl as defined herein above. Non-limiting examples of suitable C₁₋₆alkoxy include methoxy, ethoxy, propoxy, isopropoxy, butoxy, isobutoxy, sec-butoxy, tert-butoxy, pentyloxy neo-pentyloxy, iso-pentyloxy and hexyloxy.

The terms “heterocyclyl” or “heterocycloakyl” or “heterocyclo”, as a group or part of a group, refer to non-aromatic, fully saturated or partially unsaturated cyclic groups (for example, 3 to 7 member monocyclic, 7 to 11 member bicyclic, or comprising a total of 3 to 10 ring atoms) which have at least one heteroatom in at least one carbon atom-containing ring; wherein said ring may be fused to an aryl, cycloalkyl, heteroaryl or heterocyclyl ring. Each ring of the heterocyclyl group containing a heteroatom may have 1, 2, 3 or 4 heteroatoms selected from N, O and/or S, where the N and S heteroatoms may optionally be oxidized and the N heteroatoms may optionally be quaternized; and wherein at least one carbon atom of heterocyclyl can be oxidized to form at least one C═O. The heterocyclic group may be attached at any heteroatom or carbon atom of the ring or ring system, where valence allows. The rings of multi-ring heterocycles may be fused, bridged and/or joined through one or more spiro atoms.

Non limiting exemplary heterocyclic groups include aziridinyl, oxiranyl, thiiranyl, piperidinyl, azetidinyl, oxetanyl, pyrrolidinyl, thietanyl, 2-imidazolinyl, pyrazolidinyl imidazolidinyl, isoxazolinyl, oxazolidinyl, isoxazolidinyl, thiazolidinyl, isothiazolidinyl, piperidinyl, succinimidyl, 3H-indolyl, indolinyl, isoindolinyl, chromanyl (also known as 3,4-dihydrobenzo[b]pyranyl), 2H-pyrrolyl, 1-pyrrolinyl, 2-pyrrolinyl, 3-pyrrolinyl, 4H-quinolizinyl, 2-oxopiperazinyl, piperazinyl, homopiperazinyl, 2-pyrazolinyl, 3-pyrazolinyl, tetrahydro-2H-pyranyl, 2H-pyranyl, 4H-pyranyl, 3,4-dihydro-2H-pyranyl, 3-dioxolanyl, 1,4-dioxanyl, 2,5-dioximidazolidinyl, 2-oxopiperidinyl, 2-oxopyrrolodinyl, indolinyl, tetrahydropyranyl, tetrahydrofuranyl, tetrahydrothiophenyl, tetrahydroquinolinyl, tetrahydroisoquinolin-1-yl, tetrahydroisoquinolin-2-yl, tetrahydroisoquinolin-3-yl, tetrahydroisoquinolin-4-yl, thiomorpholin-4-yl, thiomorpholin-4-ylsulfoxide, thiomorpholin-4-ylsulfone, 1,3-dioxolanyl, 1,4-oxathianyl, 1,4-dithianyl, 1,3,5-trioxanyl, 1H-pyrrolizinyl, tetrahydro-1,1-dioxothiophenyl, N-formylpiperazinyl, and morpholin-4-yl. The term “aziridinyl” as used herein includes aziridin-1-yl and aziridin-2-yl. The term “oxiyranyl” as used herein includes oxiyranyl-2-yl. The term “thiiranyl” as used herein includes thiiran-2-yl. The term “azetidinyl” as used herein includes azetidin-1-yl, azetidin-2-yl and azetidin-3-yl. The term “oxetanyl” as used herein includes oxetan-2-yl and oxetan-3-yl. The term “thietanyl” as used herein includes thietan-2-yl and thietan-3-yl. The term “pyrrolidinyl” as used herein includes pyrrolidin-1-yl, pyrrolidin-2-yl and pyrrolidin-3-yl. The term “tetrahydrofuranyl” as used herein includes tetrahydrofuran-2-yl and tetrahydrofuran-3-yl. The term “tetrahydrothiophenyl” as used herein includes tetrahydrothiophen-2-yl and tetrahydrothiophen-3-yl. The term “succinimidyl” as used herein includes succinimid-1-yl and succinimid-3-yl. The term “dihydropyrrolyl” as used herein includes 2,3-dihydropyrrol-1-yl, 2,3-dihydro-1H-pyrrol-2-yl, 2,3-dihydro-1H-pyrrol-3-yl, 2,5-dihydropyrrol-1-yl, 2,5-dihydro-1H-pyrrol-3-yl and 2,5-dihydropyrrol-5-yl. The term “2H-pyrrolyl” as used herein includes 2H-pyrrol-2-yl, 2H-pyrrol-3-yl, 2H-pyrrol-4-yl and 2H-pyrrol-5-yl. The term “3H-pyrrolyl” as used herein includes 3H-pyrrol-2-yl, 3H-pyrrol-3-yl, 3H-pyrrol-4-yl and 3H-pyrrol-5-yl. The term “dihydrofuranyl” as used herein includes 2,3-dihydrofuran-2-yl, 2,3-dihydrofuran-3-yl, 2,3-dihydrofuran-4-yl, 2,3-dihydrofuran-5-yl, 2,5-dihydrofuran-2-yl, 2,5-dihydrofuran-3-yl, 2,5-dihydrofuran-4-yl and 2,5-dihydrofuran-5-yl. The term “dihydrothiophenyl” as used herein includes 2,3-dihydrothiophen-2-yl, 2,3-dihydrothiophen-3-yl, 2,3-dihydrothiophen-4-yl, 2,3-dihydrothiophen-5-yl, 2,5-dihydrothiophen-2-yl, 2,5-dihydrothiophen-3-yl, 2,5-dihydrothiophen-4-yl and 2,5-dihydrothiophen-5-yl. The term “imidazolidinyl” as used herein includes imidazolidin-1-yl, imidazolidin-2-yl and imidazolidin-4-yl. The term “pyrazolidinyl” as used herein includes pyrazolidin-1-yl, pyrazolidin-3-yl and pyrazolidin-4-yl. The term “imidazolinyl” as used herein includes imidazolin-1-yl, imidazolin-2-yl, imidazolin-4-yl and imidazolin-5-yl. The term “pyrazolinyl” as used herein includes 1-pyrazolin-3-yl, 1-pyrazolin-4-yl, 2-pyrazolin-1-yl, 2-pyrazolin-3-yl, 2-pyrazolin-4-yl, 2-pyrazolin-5-yl, 3-pyrazolin-1-yl, 3-pyrazolin-2-yl, 3-pyrazolin-3-yl, 3-pyrazolin-4-yl and 3-pyrazolin-5-yl. The term “dioxolanyl” also known as “1,3-dioxolanyl” as used herein includes dioxolan-2-yl, dioxolan-4-yl and dioxolan-5-yl. The term “dioxolyl” also known as “1,3-dioxolyl” as used herein includes dioxol-2-yl, dioxol-4-yl and dioxol-5-yl. The term “oxazolidinyl” as used herein includes oxazolidin-2-yl, oxazolidin-3-yl, oxazolidin-4-yl and oxazolidin-5-yl. The term “isoxazolidinyl” as used herein includes isoxazolidin-2-yl, isoxazolidin-3-yl, isoxazolidin-4-yl and isoxazolidin-5-yl. The term “oxazolinyl” as used herein includes 2-oxazolinyl-2-yl, 2-oxazolinyl-4-yl, 2-oxazolinyl-5-yl, 3-oxazolinyl-2-yl, 3-oxazolinyl-4-yl, 3-oxazolinyl-5-yl, 4-oxazolinyl-2-yl, 4-oxazolinyl-3-yl, 4-oxazolinyl-4-yl and 4-oxazolinyl-5-yl. The term “isoxazolinyl” as used herein includes 2-isoxazolinyl-3-yl, 2-isoxazolinyl-4-yl, 2-isoxazolinyl-5-yl, 3-isoxazolinyl-3-yl, 3-isoxazolinyl-4-yl, 3-isoxazolinyl-5-yl, 4-isoxazolinyl-2-yl, 4-isoxazolinyl-3-yl, 4-isoxazolinyl-4-yl and 4-isoxazolinyl-5-yl. The term “thiazolidinyl” as used herein includes thiazolidin-2-yl, thiazolidin-3-yl, thiazolidin-4-yl and thiazolidin-5-yl. The term “isothiazolidinyl” as used herein includes isothiazolidin-2-yl, isothiazolidin-3-yl, isothiazolidin-4-yl and isothiazolidin-5-yl. The term “thiazolinyl” as used herein includes 2-thiazolinyl-2-yl, 2-thiazolinyl-4-yl, 2-thiazolinyl-5-yl, 3-thiazolinyl-2-yl, 3-thiazolinyl-4-yl, 3-thiazolinyl-5-yl, 4-thiazolinyl-2-yl, 4-thiazolinyl-3-yl, 4-thiazolinyl-4-yl and 4-thiazolinyl-5-yl. The term “isothiazolinyl” as used herein includes 2-isothiazolinyl-3-yl, 2-isothiazolinyl-4-yl, 2-isothiazolinyl-5-yl, 3-isothiazolinyl-3-yl, 3-isothiazolinyl-4-yl, 3-isothiazolinyl-5-yl, 4-isothiazolinyl-2-yl, 4-isothiazolinyl-3-yl, 4-isothiazolinyl-4-yl and 4-isothiazolinyl-5-yl. The term “piperidyl” also known as “piperidinyl” as used herein includes piperid-1-yl, piperid-2-yl, piperid-3-yl and piperid-4-yl. The term “dihydropyridinyl” as used herein includes 1,2-dihydropyridin-1-yl, 1,2-dihydropyridin-2-yl, 1,2-dihydropyridin-3-yl, 1,2-dihydropyridin-4-yl, 1,2-dihydropyridin-5-yl, 1,2-dihydropyridin-6-yl, 1,4-dihydropyridin-1-yl, 1,4-dihydropyridin-2-yl, 1,4-dihydropyridin-3-yl, 1,4-dihydropyridin-4-yl, 2,3-dihydropyridin-2-yl, 2,3-dihydropyridin-3-yl, 2,3-dihydropyridin-4-yl, 2,3-dihydropyridin-5-yl, 2,3-dihydropyridin-6-yl, 2,5-dihydropyridin-2-yl, 2,5-dihydropyridin-3-yl, 2,5-dihydropyridin-4-yl, 2,5-dihydropyridin-5-yl, 2,5-dihydropyridin-6-yl, 3,4-dihydropyridin-2-yl, 3,4-dihydropyridin-3-yl, 3,4-dihydropyridin-4-yl, 3,4-dihydropyridin-5-yl and 3,4-dihydropyridin-6-yl. The term “tetrahydropyridinyl” as used herein includes 1,2,3,4-tetrahydropyridin-1-yl, 1,2,3,4-tetrahydropyridin-2-yl, 1,2,3,4-tetrahydropyridin-3-yl, 1,2,3,4-tetrahydropyridin-4-yl, 1,2,3,4-tetrahydropyridin-5-yl, 1,2,3,4-tetrahydropyridin-6-yl, 1,2,3,6-tetrahydropyridin-1-yl, 1,2,3,6-tetrahydropyridin-2-yl, 1,2,3,6-tetrahydropyridin-3-yl, 1,2,3,6-tetrahydropyridin-4-yl, 1,2,3,6-tetrahydropyridin-5-yl, 1,2,3,6-tetrahydropyridin-6-yl, 2,3,4,5-tetrahydropyridin-2-yl, 2,3,4,5-tetrahydropyridin-3-yl, 2,3,4,5-tetrahydropyridin-4-yl, 2,3,4,5-tetrahydropyridin-5-yl and 2,3,4,5-tetrahydropyridin-6-yl. The term “tetrahydropyranyl” also known as “oxanyl” or “tetrahydro-2H-pyranyl”, as used herein includes tetrahydropyran-2-yl, tetrahydropyran-3-yl and tetrahydropyran-4-yl. The term “2H-pyranyl” as used herein includes 2H-pyran-2-yl, 2H-pyran-3-yl, 2H-pyran-4-yl, 2H-pyran-5-yl and 2H-pyran-6-yl. The term “4H-pyranyl” as used herein includes 4H-pyran-2-yl, 4H-pyran-3-yl and 4H-pyran-4-yl. The term “3,4-dihydro-2H-pyranyl” as used herein includes 3,4-dihydro-2H-pyran-2-yl, 3,4-dihydro-2H-pyran-3-yl, 3,4-dihydro-2H-pyran-4-yl, 3,4-dihydro-2H-pyran-5-yl and 3,4-dihydro-2H-pyran-6-yl. The term “3,6-dihydro-2H-pyranyl” as used herein includes 3,6-dihydro-2H-pyran-2-yl, 3,6-dihydro-2H-pyran-3-yl, 3,6-dihydro-2H-pyran-4-yl, 3,6-dihydro-2H-pyran-5-yl and 3,6-dihydro-2H-pyran-6-yl. The term “tetrahydrothiophenyl”, as used herein includes tetrahydrothiophen-2-yl, tetrahydrothiophenyl-3-yl and tetrahydrothiophenyl-4-yl. The term “2H-thiopyranyl” as used herein includes 2H-thiopyran-2-yl, 2H-thiopyran-3-yl, 2H-thiopyran-4-yl, 2H-thiopyran-5-yl and 2H-thiopyran-6-yl. The term “4H-thiopyranyl” as used herein includes 4H-thiopyran-2-yl, 4H-thiopyran-3-yl and 4H-thiopyran-4-yl. The term “3,4-dihydro-2H-thiopyranyl” as used herein includes 3,4-dihydro-2H-thiopyran-2-yl, 3,4-dihydro-2H-thiopyran-3-yl, 3,4-dihydro-2H-thiopyran-4-yl, 3,4-dihydro-2H-thiopyran-5-yl and 3,4-dihydro-2H-thiopyran-6-yl. The term “3,6-dihydro-2H-thiopyranyl” as used herein includes 3,6-dihydro-2H-thiopyran-2-yl, 3,6-dihydro-2H-thiopyran-3-yl, 3,6-dihydro-2H-thiopyran-4-yl, 3,6-dihydro-2H-thiopyran-5-yl and 3,6-dihydro-2H-thiopyran-6-yl. The term “piperazinyl” also known as “piperazidinyl” as used herein includes piperazin-1-yl and piperazin-2-yl. The term “morpholinyl” as used herein includes morpholin-2-yl, morpholin-3-yl and morpholin-4-yl. The term “thiomorpholinyl” as used herein includes thiomorpholin-2-yl, thiomorpholin-3-yl and thiomorpholin-4-yl. The term “dioxanyl” as used herein includes 1,2-dioxan-3-yl, 1,2-dioxan-4-yl, 1,3-dioxan-2-yl, 1,3-dioxan-4-yl, 1,3-dioxan-5-yl and 1,4-dioxan-2-yl. The term “dithianyl” as used herein includes 1,2-dithian-3-yl, 1,2-dithian-4-yl, 1,3-dithian-2-yl, 1,3-dithian-4-yl, 1,3-dithian-5-yl and 1,4-dithian-2-yl. The term “oxathianyl” as used herein includes oxathian-2-yl and oxathian-3-yl. The term “trioxanyl” as used herein includes 1,2,3-trioxan-4-yl, 1,2,3-trioxan-5-yl, 1,2,4-trioxan-3-yl, 1,2,4-trioxan-5-yl, 1,2,4-trioxan-6-yl and 1,3,4-trioxan-2-yl. The term “azepanyl” as used herein includes azepan-1-yl, azepan-2-yl, azepan-3-yl and azepan-4-yl. The term “homopiperazinyl” as used herein includes homopiperazin-1-yl, homopiperazin-2-yl, homopiperazin-3-yl and homopiperazin-4-yl. The term “indolinyl” as used herein includes indolin-1-yl, indolin-2-yl, indolin-3-yl, indolin-4-yl, indolin-5-yl, indolin-6-yl, and indolin-7-yl. The term “quinolizinyl” as used herein includes quinolizidin-1-yl, quinolizidin-2-yl, quinolizidin-3-yl and quinolizidin-4-yl. The term “isoindolinyl” as used herein includes isoindolin-1-yl, isoindolin-2-yl, isoindolin-3-yl, isoindolin-4-yl, isoindolin-5-yl, isoindolin-6-yl, and isoindolin-7-yl. The term “3H-indolyl” as used herein includes 3H-indol-2-yl, 3H-indol-3-yl, 3H-indol-4-yl, 3H-indol-5-yl, 3H-indol-6-yl, and 3H-indol-7-yl. The term “quinolizinyl” as used herein includes quinolizidin-1-yl, quinolizidin-2-yl, quinolizidin-3-yl and quinolizidin-4-yl. The term “tetrahydroquinolinyl” as used herein includes tetrahydroquinolin-1-yl, tetrahydroquinolin-2-yl, tetrahydroquinolin-3-yl, tetrahydroquinolin-4-yl, tetrahydroquinolin-5-yl, tetrahydroquinolin-6-yl, tetrahydroquinolin-7-yl and tetrahydroquinolin-8-yl. The term “tetrahydroisoquinolinyl” as used herein includes tetrahydroisoquinolin-1-yl, tetrahydroisoquinolin-2-yl, tetrahydroisoquinolin-3-yl, tetrahydroisoquinolin-4-yl, tetrahydroisoquinolin-5-yl, tetrahydroisoquinolin-6-yl, tetrahydroisoquinolin-7-yl and tetrahydroisoquinolin-8-yl. The term “chromanyl” as used herein includes chroman-2-yl, chroman-3-yl, chroman-4-yl, chroman-5-yl, chroman-6-yl, chroman-7-yl and chroman-8-yl. The term “1H-pyrrolizine” as used herein includes 1H-pyrrolizin-1-yl, 1H-pyrrolizin-2-yl, 1H-pyrrolizin-3-yl, 1H-pyrrolizin-5-yl, 1H-pyrrolizin-6-yl and 1H-pyrrolizin-7-yl. The term “3H-pyrrolizine” as used herein includes 3H-pyrrolizin-1-yl, 3H-pyrrolizin-2-yl, 3H-pyrrolizin-3-yl, 3H-pyrrolizin-5-yl, 3H-pyrrolizin-6-yl and 3H-pyrrolizin-7-yl.

The term “heteroaryl” as a group or part of a group, refers but is not limited to 5 to 12 carbon-atom aromatic rings or ring systems containing 1 or 2 rings which can be fused together or linked covalently, typically containing 5 to 6 atoms; at least one of which is aromatic in which one or more carbon atoms in one or more of these rings can be replaced by N, O and/or S atoms where the N and S heteroatoms may optionally be oxidized and the N heteroatoms may optionally be quaternized, and wherein at least one carbon atom of said heteroaryl can be oxidized to form at least one C═O. Such rings may be fused to an aryl, cycloalkyl, heteroaryl or heterocyclyl ring. Non-limiting examples of such heteroaryl, include: pyrrolyl, furanyl, thiophenyl, pyrazolyl, imidazolyl, oxazolyl, isoxazolyl, thiazolyl, isothiazolyl, triazolyl, oxadiazolyl, thiadiazolyl, tetrazolyl, oxatriazolyl, thiatriazolyl, pyridinyl, pyrimidinyl, pyrazinyl, pyridazinyl, oxazinyl, dioxinyl, thiazinyl, triazinyl, imidazo[2,1-b][1,3]thiazolyl, thieno[3,2-b]furanyl, thieno[3,2-b]thiophenyl, thieno[2,3-d][1,3]thiazolyl, thieno[2,3-d]imidazolyl, tetrazolo[1,5-a]pyridinyl, indolyl, indolizinyl, isoindolyl, benzofuranyl, isobenzofuranyl, benzothiophenyl, isobenzothiophenyl, indazolyl, benzimidazolyl, 1,3-benzoxazolyl, 1,2-benzisoxazolyl, 2,1-benzisoxazolyl, 1,3-benzothiazolyl, 1,2-benzoisothiazolyl, 2,1-benzoisothiazolyl, benzotriazolyl, 1,2,3-benzoxadiazolyl, 2,1,3-benzoxadiazolyl, 1,2,3-benzothiadiazolyl, 2,1,3-benzothiadiazolyl, benzo[d]oxazol-2(3H)-one, 2,3-dihydro-benzofuranyl, thienopyridinyl, purinyl, imidazo[1,2-a]pyridinyl, 6-oxo-pyridazin-1(6H)-yl, 2-oxopyridin-1(2H)-yl, 1,3-benzodioxolyl, quinolinyl, isoquinolinyl, cinnolinyl, quinazolinyl, quinoxalinyl; preferably said heteroaryl group is selected from the group consisting of pyridyl, 1,3-benzodioxolyl, benzo[d]oxazol-2(3H)-one, 2,3-dihydro-benzofuranyl, pyrazinyl, pyrazolyl, pyrrolyl, isoxazolyl, thiophenyl, imidazolyl, benzimidazolyl, pyrimidinyl, triazolyl and thiazolyl.

In some embodiments the deposition precursor comprises at least one phosphinimide ligand (L¹) having a structure according to formula (I), wherein:
R¹ is selected from the group comprising H, an optionally substituted hydrocarbyl group, optionally substituted amino group, and an optionally substituted silyl group;
R² is selected from the group comprising H, an optionally substituted hydrocarbyl group, optionally substituted amino group, and an optionally substituted silyl group;
R³ is selected from the group comprising H, an optionally substituted hydrocarbyl group, an optionally substituted amino group, and an optionally substituted silyl group;
with the proviso that at least one of R¹, R², and R³ is not H.

In some embodiments the deposition precursor comprises at least one phosphinimide ligand (L¹) having a structure according to formula (I), wherein:
R¹ is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, tri-C₁₋₆alkylsilyl;
R² is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, and tri-C₁₋₆alkylsilyl;
R³ is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, and tri-C₁₋₆alkylsilyl.

In some embodiments the deposition precursor comprises at least one phosphinimide ligand (L¹) having a structure according to formula (I), wherein:
R¹ is selected from the group comprising H, C₁₋₆alkyl, C₃₋₆cycloalkyl, C₃₋₆cycloalkyl substituted with C₁₋₆alkyl, aryl and aryl substituted with C₁₋₆alkyl; preferably R¹ is selected from the group comprising methyl, ethyl, n-propyl, iso-propyl, tert-butyl, n-butyl, iso-butyl, sec-butyl, C₃₋₆cycloalkyl, and C₃₋₆cycloalkyl substituted with methyl, ethyl, n-propyl, iso-propyl, n-butyl, sec-butyl, iso-butyl, or tert-butyl;
R² is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, NH₂, mono-C₁₋₆alkylamino, di-C₁₋₆alkylamino, SiH₃, mono-C₁₋₆alkylsilyl, di-C₁₋₆alkylsilyl, and tri-C₁₋₆alkylsilyl; preferably R² is selected from the group comprising H, C₁₋₆alkyl, C₂₋₆alkenyl, C₂₋₁₆alkynyl, C₃₋₈cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, tri-C₁₋₆alkylsilyl; preferably R² is selected from the group comprising H, methyl, ethyl, n-propyl, i-propyl, n-butyl, i-butyl, sec-butyl, t-butyl, n-pentyl, neo-pentyl, i-pentyl, hexyl, cyclopentadienyl, phenyl, methyl-cyclopentadienyl (MeCp), di-methyl-cyclopentadienyl (Me₂Cp), i-propyl-cyclopentadienyl (i-PrCp), t-butyl-cyclopentadienyl (t-BuCp), trimethylsilyl-cyclopentadienyl (TMSCp), methyl-phenyl (MePh), ethyl-phenyl (EtPh), —NH₂, mono-methylamino, mono-ethylamino, di-methylamino, di-ethylamino, —SiH₃, mono-methylsilyl, mono-ethylsilyl, di-methylsilyl, di-ethylsilyl, tri-methylsilyl, and tri-ethylsilyl;
R³ is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, NH₂, mono-C₁₋₆alkylamino, di-C₁₋₆alkylamino, SiH₃, mono-C₁₋₆alkylsilyl, di-C₁₋₆alkylsilyl, tri-C₁₋₆alkylsilyl; preferably R³ is selected from the group comprising H, C₁₋₆alkyl, C₂₋₆alkenyl, C₂₋₆alkynyl, C₃₋₈cycloalkyl, aryl, aryl substituted with C₁₋₆alkyl or trimethylsilyl, NH₂, mono-C₁₋₆alkylamino, di-C₁₋₆alkylamino, SiH₃, mono-C₁₋₆alkylsilyl, di-C₁₋₆alkylsilyl, tri-C₁₋₆alkylsilyl; preferably R³ is selected from the group comprising H, methyl, ethyl, n-propyl, i-propyl, n-butyl, i-butyl, sec-butyl, t-butyl, n-pentyl, neo-pentyl, i-pentyl, hexyl, cyclopentadienyl, phenyl, methyl-cyclopentadienyl (MeCp), di-methyl-cyclopentadienyl (Me₂Cp), i-propyl-cyclopentadienyl (i-PrCp), t-butyl-cyclopentadienyl (t-BuCp), trimethylsilyl-cyclopentadienyl (TMSCp), methyl-phenyl (MePh), ethyl-phenyl (EtPh), —NH₂, mono-methylamino, mono-ethylamino, di-methylamino, di-ethylamino, tri-methylamino, tri-ethylamino, —SiH₃, mono-methylsilyl, mono-ethylsilyl, di-methylsilyl, di-ethylsilyl, tri-methylsilyl, and tri-ethylsilyl.

In some embodiments at least one of R¹, R², and R³ is not a hydrogen atom. In some embodiments at least two of R¹, R², and R³ is not a hydrogen atom.

In some embodiments, each of R¹, R², and R³ is independently selected from C₁₋₁₀alkyl; preferably each of R¹, R², and R³ is an independently selected C₁₋₆alkyl.

It should be understood that within the scope of the present disclosure the deposition precursor may comprise any combination of the aforementioned types of ligands.

In some embodiments the layer is a metal (M) nitride, metal (M) oxide, metal (M) phosphide, a P-doped metal (M) nitride, metal (M) boride, metal (M) carbide, or a metal (M) sulfide.

In some embodiments, the layer is a N-doped metal (M) oxide, N-doped metal (M) nitride, N-doped metal (M) phosphide, N-doped metal (M) boride, N-doped metal (M) carbide, N-doped metal (M) sulfide, or N-doped metal (M) silicide. Doping levels for N doping can range from 0.01 to 10 atomic percent, unless these elements are already implied in the composition.

In some embodiments, the layer is a P-doped metal (M) nitride, P-doped metal (M) phosphide, P-doped metal (M) boride, P-doped metal (M) carbide, P-doped metal (M) sulfide, or P-doped metal (M) silicide. Doping levels for P doping can range from 0.01 to 10 atomic percent, unless these elements are already implied in the composition.

In some embodiments, the deposition precursor comprises one or more identical ligands of formula (I); these compounds can also be referred to as homoleptic ylides.

In some embodiments the deposition precursor comprises or consists of a structure according to M(L¹)₄, wherein M is selected from the group comprising a group 4 metal, V, and Mo; preferably M is selected from the group comprising Hf, Zr, Ti, V, and Mo.

In some embodiments the deposition precursor comprises or consists of a structure according to formula (Ia):

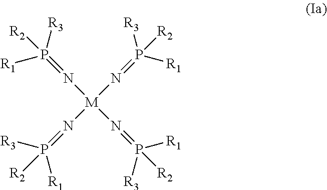

wherein,
M is selected from the group comprising a group 4 metal, V, and Mo; preferably M is selected from the group comprising Hf, Zr, Ti, V and Mo;
R¹, R², and R³ are as described herein.

In some embodiments the deposition precursor comprises or consists of a structure according to M(L¹)₃ or a dimer thereof, wherein M is selected from the group comprising Al, In, Ga, and a rare earth metal; preferably M is selected from the group comprising Al, In, Ga, a lanthanide, preferably Sc, Y, La, Ce, Pr, Nd, Er, Tm, and Lu.

In some embodiments the deposition precursor comprises or consists of a structure according to formulae (Ib) or (Ic):

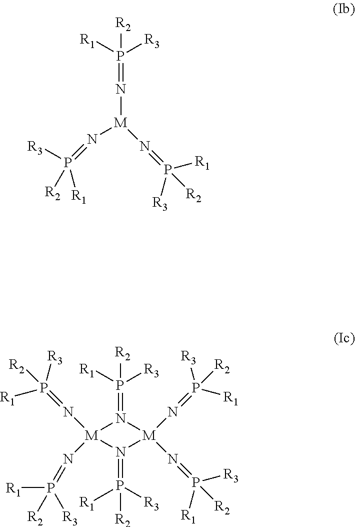

wherein,
M is selected from the group comprising Al, In, Ga, and a rare earth metal; preferably M is selected from the group comprising Al, In, Ga, a lanthanide, preferably Sc, Y, La, Ce, Pr, Nd, Er, Tm, and Lu;
R¹, R², and R³ are as described herein.

As used herein, a compound wherein different ligands are linked to the same central metal atom are known in the art as heteroleptic complexes.

In some embodiments, the deposition precursor comprises at least one phosphinimide ligand (L¹) and at least one further ligand (L²), wherein said further ligand (L²) is selected from the group comprising cyclopentadienyl ligands, amido ligands, imido ligands, amidinate, halide ligands, alkyl ligands, alkoxide ligands, siloxy ligands, diketonate ligands, 1,4-diazabutadiene ligands, amidate ligands, alkylamido ligands, oxo ligands, hydrido ligands, and guanidinate ligands.

In some embodiments, the one or more further ligand (L²) is a cyclopentadienyl ligand of formula (1):

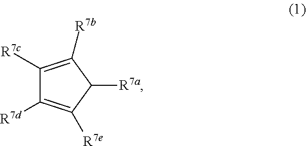

wherein
R^{7a} is selected from the group comprising H, C₁₋₈alkyl, and —SiR₃^{9a}, wherein R^{9a} is C₁₋₆alkyl; preferably R^{7a} is selected from the group comprising H, C₁₋₆alkyl, and —SiR₃^{9a}, wherein R^{9a} is C₁₋₄ alkyl; preferably R^{7a} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
R^{7b} is selected from the group comprising H, C₁₋₈alkyl, and —SiR₃^{9b}, wherein R^{9b} is C₁₋₆alkyl; preferably R^{7b} is selected from the group comprising H, C₁₋₆alkyl, and —SiR₃^{9a}, wherein R^{9b} is C₁₋₄alkyl; preferably R^{7b} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
R^{7c} is selected from the group comprising H, C₁₋₈alkyl, and —SiR₃^{9c}, wherein R^{9c} is C₁₋₆ alkyl; preferably R^{7c} is selected from the group comprising H, C₁₋₆alkyl, and —SiR₃^{9c}, wherein R^{9c} is C₁₋₄alkyl; preferably R^{7c} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
R^{7d} is selected from the group comprising H, C₁₋₈alkyl, and —SiR₃^{9d}, wherein R^{9d} is C₁₋₆alkyl; preferably R^{7d} is selected from the group comprising H, C₁₋₆alkyl, and —SiR₃^{9d}, wherein R^{9d} is C₁₋₄alkyl; preferably R^{7d} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
R^{7e} is selected from the group comprising H, C₁₋₈alkyl, and —SiR₃^{9e}, wherein R^{9e} is C₁₋₆ alkyl; preferably R^{7e} is selected from the group comprising H, C₁₋₆alkyl, and —SiR₃^{9e}, wherein R^{9e} is C₁₋₄alkyl; preferably R^{7e} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl. In some embodiments the cyclopentadienyl ligand is selected from the group comprising cyclopentadienyl, methylcyclopentadienyl, ethylcyclopentadienyl isopropylcyclopentadienyl, tert-butylcyclopentadienyl, trimethylsilylcyclopentadienyl, pentamethylcyclopentadienyl, 1,2,4-triisopropylcyclopentadienyl and 1,2,4-tri-tert-butylcyclopentadienyl.

In some embodiments, the cyclopentadienyl ligand binds to the metal in η-1, η-3, or η-5 coordination modes. The Greek letter eta (i) followed by a number indicates the number of contiguous atoms of the same type within a ligand are all simultaneously bonded to the metal atom. Preferably, the cyclopentadienyl ligand binds to the metal in η-5 coordination mode.

In some embodiments, the one or more further ligand is an amido (L²) ligand of formula (2):

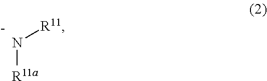

wherein
R¹¹ is independently selected from the group comprising H, C₁₋₈alkyl, and —SiR₃¹², wherein R¹² is C₁₋₆alkyl; preferably R¹¹ is selected from the group comprising H, C₁₋₆alkyl, and —SiR₃¹², wherein R¹² is C₁₋₄alkyl; preferably R¹¹ is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
R^{11a} is independently selected from the group comprising H, C₁₋₈alkyl, and —SiR₃^{12a}, wherein R^{12a} is C₁₋₆alkyl; preferably R^{11a} is selected from the group comprising H, C₁₋₆alkyl, and —SiR₃^{12a}, wherein R^{12a} is C₁₋₄alkyl; preferably R^{11a} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
wherein at least one of R¹¹ or R^{11a} is not H.

In some embodiments the amido ligand is selected from the group comprising dimethylamido, diethylamido, ethylmethylamido, diisopropylamido, tert-butylamido, and bis(trimethylsilyl)amido.

In some embodiments, the one or more further ligand (L²) is an imido ligand of formula (3)

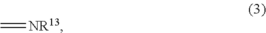

wherein
R¹³ is selected from the group comprising C₁₋₈alkyl, —SiH₃, mono-C₁₋₈alkylsilyl, di-C₁₋₈alkylsilyl and tri-C₁₋₈alkylsilyl; preferably R¹³ is C₁₋₆alkyl, —SiH₃, mono-C₁₋₆alkylsilyl, di-C₁₋₆alkylsilyl and tri-C₁₋₆alkylsilyl; preferably R¹³ is selected from the group comprising methyl, ethyl, n-propyl, iso-propyl, tert-butyl, n-butyl, iso-butyl, sec-butyl, n-pentyl, tert-pentyl, iso-pentyl, —SiH₃, monomethylsilyl, dimethylsilyl, trimethylsilyl, monoethylsilyl, diethylsilyl, triethylsilyl; more preferably R¹³ is selected from the group comprising tert-butyl, tert-pentyl, trimethylsilyl, and triethylsilyl.

In some embodiments the imido ligand is selected from the group comprising methylimido, ethylimido, isopropylimido, isobutylimido, tert-butylimido, tert-pentylimido and trimethylsilylimido.

In some embodiments, the one or more further ligand (L²) is an amidinate ligand of formula (4) or any resonance structures thereof

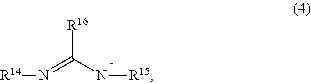

wherein
R¹⁴ is C₁₋₈alkyl; preferably R¹⁴ is C₁₋₆alkyl; preferably R¹⁴ is selected from the group comprising methyl, ethyl, n-propyl, iso-propyl, tert-butyl, n-butyl, iso-butyl, sec-butyl, n-pentyl, tert-pentyl, iso-pentyl and cyclohexyl;
R¹⁵ is C₁₋₈alkyl; preferably R¹⁵ is C₁₋₆alkyl; preferably R¹⁵ is selected from the group comprising methyl, ethyl, n-propyl, iso-propyl, tert-butyl, n-butyl, iso-butyl, sec-butyl, n-pentyl, tert-pentyl, iso-pentyl and cyclohexyl;
R¹⁶ is selected from the group comprising H, C₁₋₆alkyl, mono-C₁₋₆alkylamino and di-C₁₋₆alkylamino; preferably R¹⁶ is selected from the group comprising H, C₁₋₄alkyl, mono-C₁₋₄alkylamino and di-C₁₋₄alkylamino; preferably R¹⁶ is selected from the group comprising H, methyl, ethyl, n-propyl, iso-propyl, tert-butyl, n-butyl, sec-butyl, iso-butyl, dimethylamine, diethylamine, ethylmethylamine.

In some embodiments the amidinate ligand is selected from the group comprising N,N′-diethylacetamidinate, N,N′-diisopropylacetamidinate, N,N′-diisopropylformamidinate, N,N′-di-tert-butylacetamidinate and N,N′-di-tert-butylformamidinate.

In some embodiments, the one or more further ligand (L²) is a halide ligand selected from the group comprising I, Cl, F, and Br.

In some embodiments, the one or more further ligand (L²) is an alkyl ligand selected from the group comprising C₁₋₁₀alkyl; preferably C₁₋₆alkyl; preferably methyl, ethyl, n-propyl, i-propyl, n-butyl, i-butyl, sec-butyl, n-pentyl, neo-pentyl, iso-pentyl, and hexyl.

In some embodiments, the one or more further ligand (L²) is an alkoxide ligand of formula (5)

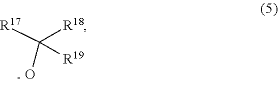

wherein,
R¹⁷ is selected from the group comprising H, C₁₋₈alkyl and aryl; preferably R¹⁷ is selected from H or C₁₋₆alkyl; preferably R¹⁷ is selected from the group comprising H, methyl, ethyl, n-propyl, iso-propyl, tert-butyl, n-butyl, iso-butyl, sec-butyl, n-pentyl, tert-pentyl, iso-pentyl and neo-pentyl;
R¹⁸ is selected from the group comprising H, C₁₋₈alkyl and aryl; preferably R¹⁸ is selected from H or C₁₋₆alkyl; preferably R¹⁸ is selected from the group comprising H, methyl, ethyl, n-propyl, iso-propyl, tert-butyl, n-butyl, iso-butyl, sec-butyl, n-pentyl, tert-pentyl, iso-pentyl and neo-pentyl;
R¹⁹ is selected from the group comprising H, C₁₋₈alkyl and aryl; preferably R¹⁹ is selected from H or C₁₋₆alkyl; preferably R¹⁹ is selected from the group comprising H, methyl, ethyl, n-propyl, iso-propyl, tert-butyl, n-butyl, sec-butyl, iso-butyl, n-pentyl, tert-pentyl, iso-pentyl and neo-pentyl.

In some embodiments the alkoxide ligand is selected from the group comprising methoxide, ethoxide, isopropoxide, tert-butoxide, 1-methoxy-2-methyl-2-propoxide, 1-dimethylamino-2-propoxide, 1-dimethylamino-2-methyl-2-propoxide, 1-ethylmethylamino-2-methyl-2-propoxide, 1-diethylamino-2-methyl-2-propoxide, 1-dimethylamino-2-methyl-2-butoxide, 1-ethylmethylamino-2-methyl-2-butoxide, 1-diethylamino-2-methyl-2-butoxide, pentoxy, tert-pentoxy, and neo-pentoxy.

In some embodiments, the one or more further ligand (L²) is a siloxy ligand of formula (8)

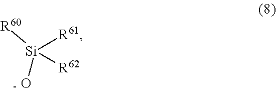

wherein,
R⁶⁰ is selected from the group comprising H, C₁₋₈alkyl and aryl; preferably R⁶⁰ is selected from H or C₁₋₆alkyl; preferably R⁶⁰ is selected from the group comprising H, methyl, ethyl, n-propyl, iso-propyl, tert-butyl, n-butyl, iso-butyl, sec-butyl, n-pentyl, tert-pentyl, iso-pentyl and neo-pentyl;
R⁶¹ is selected from the group comprising H, C₁₋₈alkyl and aryl; preferably R⁶¹ is selected from H or C₁₋₆alkyl; preferably R⁶¹ is selected from the group comprising H, methyl, ethyl, n-propyl, iso-propyl, tert-butyl, n-butyl, iso-butyl, sec-butyl, n-pentyl, tert-pentyl, iso-pentyl and neo-pentyl;
R⁶² is selected from the group comprising H, C₁₋₈alkyl and aryl; preferably R⁶² is selected from H or C₁₋₆alkyl; preferably R⁶² is selected from the group comprising H, methyl, ethyl, n-propyl, iso-propyl, tert-butyl, n-butyl, sec-butyl, iso-butyl, n-pentyl, tert-pentyl, iso-pentyl and neo-pentyl. In some embodiments the siloxide ligand is selected from methylsiloxy, dimethylsiloxy, trimethylsiloxy, dimethylethylsiloxy, diethylmethylsiloxy, triethylsiloxy, isopropylsiloxy, diisoproylsiloxy, triisopropylsiloxy, dimethylisopropylsiloxy, diisopropylmethylsiloxy, triisopropylsiloxy, diethylisopropylsiloxy, diisopropylethylsiloxy, and ethylmethylisopropylsiloxy.

In some embodiments, the one or more further ligand (L²) is a diketonate ligand of formula (6) or any resonance structures thereof

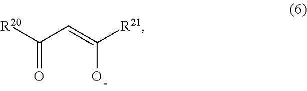

wherein
R²⁰ is selected from the group comprising C₁₋₈alkyl, C₁₋₈alkyl substituted with halogen, and aryl; preferably R²⁰ is selected from the group comprising C₁₋₆alkyl, C₁₋₆alkyl substituted with halogen and aryl; preferably R²⁰ is selected from the group comprising methyl, ethyl, n-propyl, iso-propyl, tert-butyl, n-butyl, iso-butyl, sec-butyl, n-pentyl, tert-pentyl, iso-pentyl, cyclopentyl, cyclohexyl, fluoromethyl, difluoromethyl, trifluoromethyl, chloromethyl, dichloromethyl, trichloromethyl, phenyl and toluyl;
R²¹ is selected from the group comprising C₁₋₈alkyl, C₁₋₈alkyl substituted with halogen and aryl; preferably R²¹ is selected from the group comprising C₁₋₆alkyl, C₁₋₆alkyl substituted with halogen and aryl; preferably R²¹ is selected from the group comprising methyl, ethyl, n-propyl, iso-propyl, tert-butyl, n-butyl, iso-butyl, sec-butyl, n-pentyl, tert-pentyl, iso-pentyl, cyclopentyl, cyclohexyl, fluoromethyl, difluoromethyl, trifluoromethyl, chloromethyl, dichloromethyl, trichloromethyl, phenyl and toluyl.

In some embodiments the diketonate ligand is selected from the group comprising acetylacetonate, hexafluoroacetylacetonate, 2,2,6,6-tetramethylheptane-3,5-dionate, and 1,1,1,5,5,5-hexafluoropentane-2,5-dionate.

In some embodiments, the one or more further ligand (L²) is a diazabutadiene ligand of formula (7)

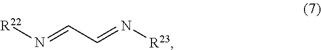

wherein
R²² is C₁₋₈alkyl; preferably R²² is C₁₋₆alkyl; preferably R²² is selected from the group comprising methyl, ethyl, n-propyl, iso-propyl, tert-butyl, n-butyl, iso-butyl, sec-butyl, n-pentyl, tert-pentyl and iso-pentyl;
R²³ is C₁₋₈alkyl; preferably R²³ is C₁₋₆alkyl; preferably R²³ is selected from the group comprising methyl, ethyl, n-propyl, iso-propyl, tert-butyl, n-butyl, iso-butyl, sec-butyl, n-pentyl, tert-pentyl and iso-pentyl.

In some embodiments the diazabutadiene ligand is selected from the group comprising 1,4-di-tert-butyl-1,4-diaza-1,3-butadiene, 1,4-diisopropyl-1,4-diaza-1,3-butadiene, 1,4-di-sec-butyl-1,4-diaza-1,3-butadiene and 1,4-di-tert-pentyl-1,4-diaza-1,3-butadiene.

In some embodiments, the one or more further ligand (L²) is an amidate ligand of formula (9) or any resonance structures thereof

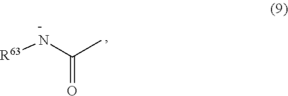

wherein
R⁶³ is selected from the group comprising H, C₁₋₈alkyl, and aryl; preferably R⁶³ is selected from the group comprising H, C₁₋₆alkyl, and aryl; preferably R⁶³ is selected from the group comprising H, methyl, ethyl, n-propyl, iso-propyl, tert-butyl, n-butyl, iso-butyl, sec-butyl, n-pentyl, tert-pentyl, iso-pentyl, phenyl and toluyl;
R⁶⁴ is selected from the group comprising H, C₁₋₈alkyl, and aryl; preferably R⁶⁴ is selected from the group comprising H, C₁₋₆alkyl, and aryl; preferably R⁶⁴ is selected from the group comprising H, methyl, ethyl, n-propyl, iso-propyl, tert-butyl, n-butyl, iso-butyl, sec-butyl, n-pentyl, tert-pentyl, iso-pentyl, phenyl and toluyl.

In some embodiments, the one or more further ligand (L²) is an alkylamino ligand selected from the group comprising tri-C₁₋₆alkylamino; preferably the alkylamino ligand is selected from the group comprising m tri-C₁₋₄alkylamino; preferably the alkylamino ligand is selected from the group comprising trimethylamino, triethylamino, and ethyldimethylamino,

In some embodiments, the one or more further ligand (L²) is an oxo ligand of formula ═O.

In some embodiments, the one or more further ligand (L²) is an hydrido ligand of formula H⁻.

In some embodiments, the one or more further ligand (L²) is a guanidinate ligand of formula (10) or any resonance structures thereof

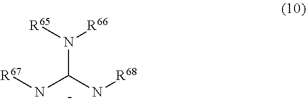

wherein,
R⁶⁵ is selected from the group comprising H, C₁₋₆alkyl; preferably R⁶⁵ is selected from the group comprising H, C₁₋₄alkyl; preferably R⁶⁵ is selected from the group comprising H, methyl, ethyl, n-propyl, iso-propyl, tert-butyl, n-butyl, sec-butyl, iso-butyl;
R⁶⁶ is selected from the group comprising H, C₁₋₆alkyl; preferably R⁶⁶ is selected from the group comprising H, C₁₋₄alkyl; preferably R⁶⁶ is selected from the group comprising H, methyl, ethyl, n-propyl, iso-propyl, tert-butyl, n-butyl, sec-butyl, iso-butyl;
R⁶⁷ is selected from the group comprising H, C₁₋₆alkyl; preferably R⁶⁷ is selected from the group comprising H, C₁₋₄alkyl; preferably R⁶⁷ is selected from the group comprising H, methyl, ethyl, n-propyl, iso-propyl, tert-butyl, n-butyl, sec-butyl, iso-butyl;
R⁶⁸ is selected from the group comprising H, C₁₋₆alkyl; preferably R⁶⁸ is selected from the group comprising H, C₁₋₄alkyl; preferably R⁶⁸ is selected from the group comprising H, methyl, ethyl, n-propyl, iso-propyl, tert-butyl, n-butyl, sec-butyl, iso-butyl.

In some embodiments the guanidinate ligand is chosen from N,N′-diisopropyl-2-dimethylamidoguanidinate, N,N′-diisopropyl-2-diethylamidoguanidinate, N,N′-diisopropyl-2,2-ethylmethylamidoguanidinate, N,N′-di-tert-butyl-2-dimethylamidoguanidinate, N,N′-di-tert-butyl-2-diethylamidoguanidinate, N,N′-di-tert-butyl-2,2-ethylmethylamidoguanidinate.

In some embodiments the one or more further ligand (L²) is selected from group consisting of: amido ligands, alkoxide ligands, siloxy ligands, amidinate ligands, cyclopentadienyl ligands; preferably L² is selected from the group comprising dimethylamido, diethylamido, ethylmethylamido, methoxy, ethoxy, isopropoxy, tert-butoxy, tert-pentoxy, trimethylsiloxy, or triethylsiloxy, N,N′-diisopropylacetamidinate, N,N′-di-tert-butylacetamidinate, N,N′-diisopropylformamidinate, N,N′-di-tert-butylformamidinate, cyclopentadienyl, methylcyclopentadienyl, ethylcyclopentadienyl, isopropylcyclopentadienyl, tert-butylcyclopentadienyl, trimethylsilylcyclopentadienyl, and pentamethylcyclopentadienyl.

In some embodiment the deposition precursor comprises or consists of a structure according to M(L¹)ₓ(L²)_{y}, wherein:
x is an integer selected from 1, 2, or 3;
y is an integer selected from 1, 2, or 3;
wherein x+y is equal to 4;
L² is as disclosed herein; preferably L² is selected from a cyclopentadienyl ligand, an alkyl ligand, and a halide ligand, and
M is selected from the group comprising a group 4 metal, V or Mo.

In some embodiments the deposition precursor comprises or consists of a structure according to formulae (IIa) or (IIb):

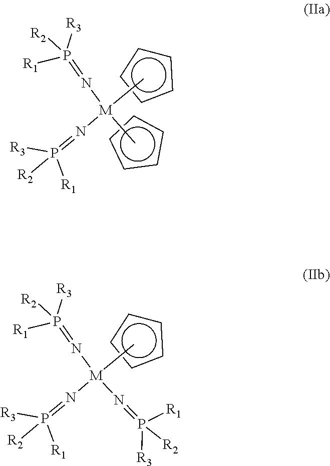

wherein,
M is selected from the group comprising a group 4 metal, V or Mo;
R¹, R², and R³ are as described herein.

In some embodiments the deposition precursor comprises or consists of a structure according to M(L¹)ₓ(L²)_{y}, wherein:
x is an integer selected from 1, 2, 3, or 4;
y is an integer selected from 1, 2, 3 or 4;
wherein x+y is equal to 2, 3, 4, 5, 6, 7 or 8;
L² is as disclosed herein; preferably L² is selected from group consisting of amido ligands, alkoxide ligands, siloxy ligands, amidinate ligands, cyclopentadienyl ligands; preferably L² is selected from the group comprising dimethylamido, diethylamido, ethylmethylamido, methoxy, ethoxy, isopropoxy, tert-butoxy, tert-pentoxy, trimethylsiloxy, or triethylsiloxy, N,N′-diisopropylacetamidinate, N,N′-di-tert-butylacetamidinate, N,N′-diisopropylformamidinate, N,N′-di-tert-butylformamidinate, cyclopentadienyl, methylcyclopentadienyl, ethylcyclopentadienyl, isopropylcyclopentadienyl, tert-butylcyclopentadienyl, trimethylsilylcyclopentadienyl, and pentamethylcyclopentadienyl; and M is selected from the group comprising a group 4 metal, a group 5 metal or a group 6 metal.

In some embodiments the deposition precursor comprises or consists of a structure according to M(L¹)(L²)₂ or a dimer thereof, wherein, L² is as disclosed herein; and
M is selected from the group comprising Al, In, Ga, B, Si, Ge, a lanthanide, and a rare earth metal.

In some embodiments the deposition precursor comprises or consists of a structure according to formulae (IIc) or (IId):

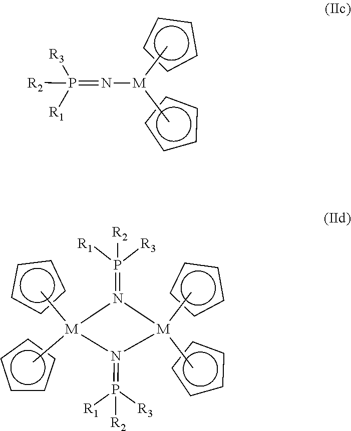

wherein,
wherein, L² is as disclosed herein; and
M is selected from the group comprising Al, In, Ga, and a rare earth metal;
R¹, R², and R³ are as described herein.

In some embodiments the deposition precursor comprises or consists of a structure according to M(L¹)ₓ(O)_{y}, wherein
(i) M is a group 5 metal, x=3 and y=1; or
(ii) M is a group 6 metal, x=2 and y=2.

In some embodiments the deposition precursor comprises or consists of a structure according to formulae (IIe) or (IIf):

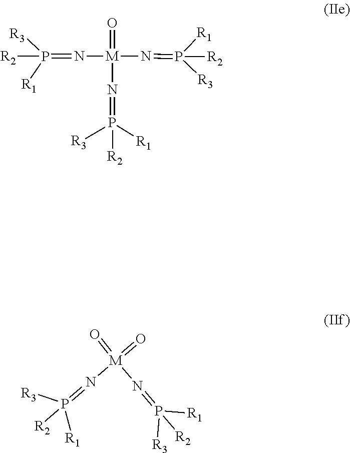

wherein,
(i) M is a group 5 metal, x=3 and y=1; or
(ii) M is a group 6 metal, x=2 and y=2;
R¹, R², and R³ are as described herein.

In some embodiments the deposition precursor comprises or consists of a structure according to M(L¹)ₓ(NR¹³)_{y}, wherein
R¹³ is selected from the group comprising C₁₋₈alkyl, —SiH₃, mono-C₁₋₈alkylsilyl, di-C₁₋₈alkylsilyl and tri-C₁₋₈alkylsilyl; preferably R¹³ is selected from the group comprising t-butyl, n-pentyl, neo-pentyl, —SiH₃, and SiMe₃;
(i) M is a group 5 metal, x=3 and y=1; or
(ii) M is a group 6 metal, x=2 and y=2.

In some embodiments the deposition precursor comprises or consists of a structure according to formula (IIg) or (IIh):

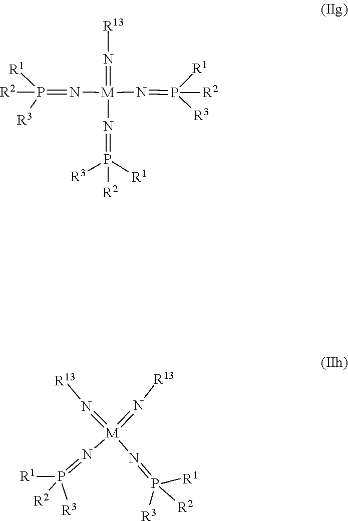

wherein,
R¹, R², and R³ are as described herein;
R¹³ is selected from the group comprising C₁₋₈alkyl, SiH₃, mono-C₁₋₈alkylsilyl, di-C₁₋₈alkylsilyl and tri-C₁₋₈alkylsilyl; preferably R¹³ is selected from the group comprising t-butyl, n-pentyl, neo-pentyl, SiH₃, and SiMe₃;
(i) M is a group 5 metal, x=3 and y=1; or
(ii) M is a group 6 metal, x=2 and y=2.

In some embodiments, the present invention provides a composition comprising a deposition precursor having a purity of at least 95.0% (by weight), as determined using an analytical method such as one or more of ¹H NMR, ¹³C NMR, gas chromatography (GC), gas chromatography mass spectrometry (GC-MS), inductively coupled plasma mass spectrometry (ICP-MS), high-performance liquid chromatography (HPLC), atomic emission spectroscopy, elemental analysis, or other analytical methods known in the art. Preferably, the composition comprises a deposition precursor having a purity of at least 96.0%, or at least 97.0%, or at least 98.0%, or at least 99.0%, or at least 99.5%, or at least 99.9%.

In some embodiments the composition of the present invention comprises at most 5.0 wt. % of halogen impurities, based on the total weight of the composition; preferably at most 4.0 wt. % of halogen impurities; preferably at most 3.0 wt. % of halogen impurities; preferably at most 2.0 wt. % of halogen impurities; preferably at most 1.0 wt. % of halogen impurities; preferably at most 0.5 wt. % of halogen impurities; preferably at most 0.1 wt. % of halogen impurities; preferably at most 100 ppm of halogen impurities; preferably at most 10 ppm of halogen impurities, based on the total weight of the composition.

In some embodiments the composition of the present invention comprises at most 1.0 wt. % of metal containing impurities, based on the total weight of the composition; preferably at most 0.1 wt. % of metal containing impurities; preferably at most 100 ppm of metal containing impurities; preferably at most 10 ppm of metal containing impurities; preferably at most 1 ppm of metal containing impurities; preferably at most 100 ppb of metal containing impurities; preferably at most 10 ppb of metal containing impurities, based on the weight of the composition.

Another aspect of the present invention relates to a vapor delivery vessel comprising the composition according to the present invention, wherein the vapor delivery vessel is constructed and arranged to supply a vapor of the deposition precursor to a reaction chamber of a vapor deposition apparatus.

In some embodiments, the vapor delivery vessel is formed from a material that is non-reactive to the composition for forming a metal containing layer on a semiconductor substrate. In some embodiments, the vapor delivery vessel may also be compliant with U.S. Department of Transportation (DOT) regulation, such as 49 C.F.R. § 178 (2021). In some embodiments, the vapor delivery vessel is formed from stainless steel (e.g., 316, 316L, 304, or 304L alloys).

The vapor delivery vessel may comprise an outer wall that encloses a cavity for storing the composition for forming a metal containing layer on a semiconductor substrate and a gas outlet for allowing a vapor of the deposition precursor to exit the cavity. The gas outlet may be seated in the outer wall of the vapor delivery vessel and may be in communication with the cavity of the vapor delivery vessel and has at least one valve positioned thereon to fluidly couple or decouple the cavity to the outside environment.

In some embodiments, the vapor delivery vessel comprises one or more other fluid inlets or outlets, in addition to the gas outlet. For example, the vapor delivery vessel may comprise a fluid inlet that is seated in the outer wall of the vapor delivery vessel and is in communication with the cavity of the vapor delivery vessel and having at least one valve positioned thereon for filling the vapor delivery vessel with the composition for forming a metal containing layer on a semiconductor substrate. Additionally, or alternatively, the vapor delivery vessel may comprise a fluid inlet that is seated in the outer wall of the vapor delivery vessel and is in communication with the cavity of the vapor delivery vessel and having at least one valve positioned thereon for flowing a carrier gas into the cavity of the vessel, either over the surface of the composition and/or through the composition.

In some embodiments, the vapor delivery vessel further comprises one or more probe members, that may comprise one or more temperature sensors, and/or one or more pressure sensors, and/or one or more level sensors.

In some embodiments, the vapor delivery vessel further comprises one or more heat transfer elements, such as, for example, fins, rods, beads, and the like, to facilitate heat transfer from the walls of the vessel to the film forming composition within the cavity, or vice versa. The one or more heat transfer elements may form a serpentine or radial path for holding the composition for forming a metal containing layer on a semiconductor substrate within the cavity and, in some cases, for directing the flow of a carrier gas over or through the composition. Such configurations are particularly useful for delivering a vapor of low-volatility liquids and solid compositions.

Yet another aspect of the present invention relates to a vapor deposition apparatus comprising:
a reaction chamber constructed and arranged to hold at least a semiconductor substrate;
a vapor delivery vessel comprising a composition comprising a deposition precursor, wherein the vapor delivery vessel is constructed and arranged to provide a vapor of the deposition precursor;
a precursor distribution and removal system configured to provide the vapor of the deposition precursor from the vapor delivery vessel to the reaction chamber and to remove the vapor of the deposition precursor from the reaction chamber; and
   a sequence controller operably connected to the precursor distribution system and removal system, and comprising a memory provided with a program configured to control the flow of the composition comprising the deposition precursor from the vapor delivery vessel to the reaction chamber by activating the precursor distribution and removal system during one or more cycles; whereby, as a result of the cycles, a layer is formed on the semiconductor substrate in the reaction chamber; wherein the deposition precursor comprises:
a central atom or ion (M); and
at least one phosphinimide ligand (L¹).

In some embodiments, the at least one phosphinimide ligand (L¹) has a structure according to formula (I):

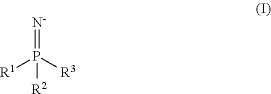

wherein,
R¹ is selected from the group comprising H, a hydrocarbyl group, amino group and a silyl group;
R² is selected from the group comprising H, a hydrocarbyl group, amino group and a silyl group;
R³ is selected from the group comprising H, a hydrocarbyl group, an amino group and a silyl group; with the proviso that at least one of R¹, R², and R³ is not H.

Further embodiments of the phosphinimide ligand (L¹) has a structure according to formula (I) have been described hereinabove.

In some embodiments, the apparatus may further comprise a reactant source constructed and arranged to provide a vapor of a reactant; wherein the precursor distribution and removal system is further configured to provide the vapor of the reactant from the reactant source to the reaction chamber; wherein the program stored in the memory is further configured to control the flow of the reactant from the reactant source to the reaction chamber during the one or more cycles.

In some embodiments, the composition comprising the deposition precursor, the one or more optional reactant(s), is provided to the reaction chamber from a temperature-controlled vessel. In some embodiments, the temperature-controlled vessel is configured for cooling the composition, and/or optional reactants.

In some embodiments the reactant is selected from the group comprising nitride reactants, oxide reactants, phosphide reactants, carbide reactants, boride reactants, reducing agents, sulfide reactants and combinations thereof.

In some embodiments, the reactant is a nitride reactant, wherein the nitride reactant is selected from the group comprising NH₃, N₂H₄, hydrazines, alkylamines, N₂ plasma, NH₃ plasma and N₂/H₂ plasma.

As used herein, a nitride reactant is a reagent that when put into contact with the deposition precursor can produce an metal nitride.

Suitable examples of hydrazines are compounds of formula

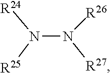

wherein
R²⁴ is selected from the group comprising H, C₁₋₈alkyl, C₃₋₁₀cycloalkyl and aryl; preferably R²⁴ is selected from the group comprising H, C₁₋₆alkyl, and aryl; preferably R²⁴ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl;
R²⁵ is selected from the group comprising H, C₁₋₈alkyl, C₃₋₁₀cycloalkyl, and aryl; preferably R²⁵ is selected from the group comprising H, C₁₋₆alkyl, and aryl; preferably R²⁵ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl;
R²⁶ is selected from the group comprising H, C₁₋₈alkyl, C₃₋₁₀cycloalkyl and aryl; preferably R²⁶ is selected from the group comprising H, C₁₋₆alkyl, and aryl; preferably R²⁶ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl;
R²⁷ is selected from the group comprising H, C₁₋₈alkyl, C₃₋₁₀cycloalkyl and aryl; preferably R²⁷ is selected from the group comprising H, C₁₋₆alkyl, and aryl; preferably R²⁷ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl.

Further non-limiting examples of suitable hydrazines include: tert-butyl-hydrazine, 1,1-dimethylhydrazine, methylhydrazine, phenylhydrazine.

Suitable examples of alkylamines are compounds of formula

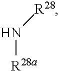

wherein
R²⁸ is C₁₋₈alkyl; preferably R²⁸ is C₁₋₆alkyl; preferably R²⁸ is selected from the group comprising methyl, ethyl, n-propyl, iso-propyl, tert-butyl, n-butyl, iso-butyl, sec-butyl, n-pentyl, tert-pentyl, iso-pentyl, phenyl, and naphthyl.
R^{28a} is H or C₁₋₈alkyl; preferably R^{28a} is H or C₁₋₆alkyl; preferably R^{28a} is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl.

Further non-limiting examples of suitable alkylamines include: tert-butylamine, isobutylamine, and tert-pentylamine.

In some embodiments, the reactant is an oxide reactant, wherein the oxide reactant is selected from the group comprising H₂O, O₂, O₃, H₂O₂, N₂O, NO₂, N₂O₄, pyridine N-oxide, and O₂ plasma.

As used herein, an oxide reactant is a reagent that when put into contact with the deposition precursor can produce a metal oxide.

In some embodiments, the reactant is a phosphide reactant is selected from the group comprising phosphine, phosphorus halides, phosphorus oxyhalides, organophosphates, organophosphites, aminophosphines, alkylphosphines, and silylphosphines.

As used herein, a phosphide reactant is a reagent that when put into contact with the deposition precursor can produce a metal phosphide.

Suitable examples of phosphorus halides include compounds of formula PX₃ or PX₅, wherein X is fluoro, chloro, bromo, or iodo. Suitable but non limited examples of phosphorus halides include: e.g., phosphorus trichloride (PCl₃), phosphorus pentachloride (PCl₅), phosphorus tribromide (PBr₃), phosphorus pentabromide (PBr₅).

Suitable examples of phosphorus oxyhalides include compounds of formula POX₃ wherein X is fluoro, chloro, bromo or iodo. Suitable but non limited examples of phosphorus oxyhalides include: e.g., phosphorus oxychloride (POCl₃), phosphorus oxybromide (POBr₃)).

Suitable examples of organophosphates include compounds of formula

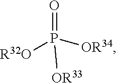

### Wherein

R³² is selected from the group comprising H, C₁₋₈alkyl, and aryl; preferably R³² is selected from the group comprising H, C₁₋₆alkyl, and aryl; preferably R³² is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R³³ is selected from the group comprising H, C₁₋₈alkyl, and aryl; preferably R³³ is selected from the group comprising H, C₁₋₆alkyl, and aryl; preferably R³³ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R³⁴ is selected from the group comprising H, C₁₋₈alkyl, and aryl; preferably R³⁴ is selected from the group comprising H, C₁₋₆alkyl, and aryl; preferably R³⁴ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
wherein only one of R³², R³³ or R³⁴ is hydrogen.

Suitable but non limited examples of organophosphates include trimethylphosphate (PO[OMe]₃), triethylphosphate (PO[OEt₃]).

Suitable examples of organophosphites include compounds of formula

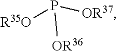

wherein
R³⁵ is selected from the group comprising H, C₁₋₈alkyl, —SiR₃^{35a} and aryl, wherein R^{35a} is C₁₋₆alkyl; preferably R³⁵ is selected from the group comprising H, C₁₋₆alkyl, —SiR₃^{35a} and aryl, wherein R^{35a} is C₁₋₆alkyl; preferably R³⁵ is selected from the group comprising H, methyl, ethyl, n-propyl, iso-propyl, tert-butyl, n-butyl, iso-butyl, sec-butyl, n-pentyl, tert-pentyl, iso-pentyl, trimethylsilyl, phenyl, and naphthyl;
R³⁶ is selected from the group comprising H, C₁₋₈alkyl, —SiR₃^{36a} and aryl, wherein R^{36a} is C₁₋₆alkyl; preferably R³⁶ is selected from the group comprising H, C₁₋₆alkyl, —SiR₃^{37a} and aryl, wherein R^{36a} is C₁₋₆alkyl; preferably R³⁶ is selected from the group comprising H, methyl, ethyl, n-propyl, iso-propyl, tert-butyl, n-butyl, iso-butyl, sec-butyl, n-pentyl, tert-pentyl, iso-pentyl, trimethylsilyl, phenyl, and naphthyl;
R³⁷ is selected from the group comprising H, C₁₋₈alkyl, —SiR₃^{37a} and aryl, wherein R^{37a} is C₁₋₆alkyl; preferably R³⁷ is selected from the group comprising H, C₁₋₆alkyl, —SiR₃^{37a} and aryl, wherein R^{37a} is C₁₋₆alkyl; preferably R³⁷ is selected from the group comprising H, methyl, ethyl, n-propyl, iso-propyl, tert-butyl, n-butyl, iso-butyl, sec-butyl, n-pentyl, tert-pentyl, iso-pentyl, trimethylsilyl, phenyl, and naphthyl;
wherein only one of R³⁵, R³⁶ or R³⁷ is hydrogen.

Suitable but non limited examples of organophosphites include trimethylphosphite (P[OMe]₃), triethylphosphite (P[OEt]₃).

Suitable examples of aminophosphines include compounds of formula

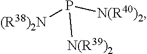

wherein
each R³⁸ is independently selected from the group comprising H, C₁₋₈alkyl, and aryl; preferably
each R³⁸ is independently selected from the group comprising H, C₁₋₆alkyl and aryl; preferably
each R³⁵ is independently selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
each R³⁹ is independently selected from the group comprising H, C₁₋₈alkyl, and aryl; preferably
each R³⁹ is independently selected from the group comprising H, C₁₋₆alkyl and aryl; preferably
each R³⁹ is independently selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
each R⁴⁰ is independently selected from the group comprising H, C₁₋₈alkyl, and aryl; preferably
each R⁴⁰ is independently selected from the group comprising H, C₁₋₆alkyl, and aryl; preferably
each R⁴⁰ is independently selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl.

Suitable but non limited examples of aminophosphines include tris(dimethylamino)phosphine (P[NMe₂]₃), tris(ethylmethylamino)phosphine (P[NEtMe]₃), and tris(diethylamino)phosphine (P[NEt₂]₃).

Suitable examples of alkylphosphines include compounds of formula

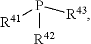

wherein
R⁴¹ is selected from H and C₁₋₈alkyl; preferably R⁴¹ is selected from H and C₁₋₆alkyl; preferably
R⁴¹ is selected from H, methyl, ethyl, n-propyl, iso-propyl, tert-butyl, n-butyl, iso-butyl, sec-butyl, n-pentyl, tert-pentyl and iso-pentyl;
R⁴² is selected from H and C₁₋₈alkyl; preferably R⁴² is selected from H and C₁₋₆alkyl; preferably
R⁴² is selected from H, methyl, ethyl, n-propyl, iso-propyl, tert-butyl, n-butyl, iso-butyl, sec-butyl, n-pentyl, tert-pentyl and iso-pentyl;
R⁴³ is selected from H and C₁₋₈alkyl; preferably R⁴³ is selected from H and C₁₋₆alkyl; preferably R⁴³ is selected from H, methyl, ethyl, n-propyl, iso-propyl, tert-butyl, n-butyl, iso-butyl, sec-butyl, n-pentyl, tert-pentyl and iso-pentyl;
wherein at least one of R⁴¹, R⁴² or R⁴³ is not hydrogen.

Suitable but non limited examples of alkylphosphines include tert-butyl phosphine (C₄H₉PH₂), triethylphosphine (P[CH₂CH₃]₃).

Suitable examples of silylphosphines include compounds of formula

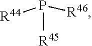

wherein
R⁴⁴ is H or Si(R^{44a})₃, wherein each R^{44a} is independently selected from the group comprising H, halogen, C₁₋₈alkyl, and aryl; preferably each R^{44a} is independently selected from the group comprising H, halogen, C₁₋₆alkyl and aryl; preferably each R^{44a} is independently selected from the group comprising H, F, Cl, Br, I, methyl, ethyl, n-propyl, iso-propyl, tert-butyl, n-butyl, iso-butyl, sec-butyl, n-pentyl, tert-pentyl, iso-pentyl, phenyl, and naphthyl;
R⁴⁵ is H or Si(R^{45a})₃, wherein each R^{45a} is independently selected from the group comprising H, halogen, C₁₋₈alkyl, and aryl; preferably each R^{45a} is independently selected from the group comprising H, halogen, C₁₋₆alkyl and aryl; preferably each R^{45a} is independently selected from the group comprising H, F, Cl, Br, I, methyl, ethyl, n-propyl, iso-propyl, tert-butyl, n-butyl, iso-butyl, sec-butyl, n-pentyl, tert-pentyl, iso-pentyl, phenyl, and naphthyl;
R⁴⁶ is H or Si(R^{46a})₃, wherein each R^{46a} is independently selected from the group comprising H, halogen, C₁₋₈alkyl, and aryl; preferably each R^{46a} is independently selected from the group comprising H, halogen, C₁₋₆alkyl and aryl; preferably each R^{46a} is independently selected from the group comprising H, F, Cl, Br, I, methyl, ethyl, n-propyl, iso-propyl, tert-butyl, n-butyl, iso-butyl, sec-butyl, n-pentyl, tert-pentyl, iso-pentyl, phenyl, and naphthyl;
wherein at least one of R⁴⁴, R⁴⁵ or R⁴⁶ is not H.

In some embodiments the silylphosphines include compounds of formula

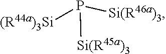

wherein each R^{44a}, R^{45a} and R^{46a} are as defined hereinabove. Suitable but non limited examples of silylphosphines include tris(trimethylsilyl)phosphine (P[SiMe₃]₃) and tri(silyl)phosphine (P[SiH₃]₃).

In some embodiments, the reactant is a reactant is a carbide reactant, wherein the carbide reactant is selected from the group comprising alkyl iodides, aryl iodides, alkyl bromides, aryl bromides, acetylene, propargyl chloride, propargyl bromide, propargyl iodide, allyl chloride, allyl bromide, allyl iodide and cyclic dienes.

As used herein, a carbide reactant is a reagent that when put into contact with the deposition precursor can produce a metal carbide.

As used herein the term “alkyl iodide” refers to a C₁₋₈alkyl group wherein one, two, or three hydrogen atoms are each replaced with an iodine atom; preferably C₁₋₆alkyl group; preferably a C₁₋₄alkyl group. Further non-limiting examples of suitable alkyl iodides include iodomethane, diiodomethane, iodoethane, 1,2-diiodoethane, 1-iodobutane.

As used herein the term “aryl iodide” refers to an aryl group wherein one, two, three, four, five or six hydrogen atoms are each replaced with an iodine atom; preferably three hydrogen atoms; preferably two hydrogen atoms; preferably one hydrogen atom. Further non-limiting examples of suitable aryl iodides include iodobenzene, 1,2-diiodobenzene, 1,3-diiodobenzene, 1,4-diiodobenzene, 1,2,3-triiodobenzene, 1,2,4-triiodobenzene, 1,3,5-triiodobenzene, 1,2,3,4-tetraiodobenzene, 1,2,3,5-tetraiodobenzene, 1,2,4,5-tetraiodobenzene, pentaidobenzene, hexaiodobenzene.

As used herein the term “alkyl bromide” refers to a C₁₋₈alkyl group wherein one, two, or three hydrogen atoms are each replaced with an bromine atom; preferably C₁₋₆alkyl group; preferably a C₁₋₄alkyl group.

As used herein the term “aryl bromide” refers to an aryl group wherein one, two, three, four, five or six hydrogen atoms are each replaced with an bromine atom; preferably three hydrogen atoms; preferably two hydrogen atoms; preferably one hydrogen atom.

Further non-limiting examples of suitable alkyl bromides include: bromoethane, 1,2-dibromoethane, 1-bromobutane.

Further non-limiting examples of suitable aryl bromides include bromobenzene, 1,2-dibromobenzene, 1,3-dibromobenzene, 1,4-dibromobenzene, 1,2,3-tribromobenzene, 1,2,4-tribromobenzene, 1,3,5-tribromobenzene, 1,2,3,4-tetrabromobenzene, 1,2,3,5-tetrabromobenzene, 1,2,4,5-tetrabromobenzene, pentabromobenzene, and hexabromobenzene.

In some embodiments, the reactant is a boride reactant, wherein the boride reactant is selected from the group comprising BF₃, BCl₃, BBr₃, BI₃, boranes, and compounds of formula

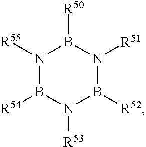

wherein
R⁵⁰ is selected from the group comprising halogen, C₁₋₈alkyl, and aryl; preferably R⁵⁰ is selected from the group comprising halogen, C₁₋₆alkyl, and aryl; preferably R⁵⁰ is selected from the group comprising halogen, C₁₋₄alkyl, and aryl; preferably R⁵⁰ is selected from the group comprising F, Cl, Br, I, C₁₋₆alkyl, and phenyl; preferably R⁵⁰ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵¹ is selected from the group comprising halogen, C₁₋₈alkyl, and aryl; preferably R⁵¹ is selected from the group comprising halogen, C₁₋₆alkyl, and aryl; preferably R⁵¹ is selected from the group comprising halogen, C₁₋₄alkyl, and aryl; preferably R⁵¹ is selected from the group comprising F, Cl, Br, I, C₁₋₆alkyl, and phenyl; preferably R⁵¹ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵² is selected from the group comprising halogen, C₁₋₈alkyl, and aryl; preferably R⁵² is selected from the group comprising halogen, C₁₋₆alkyl, and aryl; preferably R⁵² is selected from the group comprising halogen, C₁₋₄alkyl, and aryl; preferably R⁵² is selected from the group comprising F, Cl, Br, I, C₁₋₆alkyl, and phenyl; preferably R⁵² is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵³ is selected from the group comprising halogen, C₁₋₈alkyl, and aryl; preferably R⁵³ is selected from the group comprising halogen, C₁₋₆alkyl, and aryl; preferably R⁵³ is selected from the group comprising halogen, C₁₋₄alkyl, and aryl; preferably R⁵³ is selected from the group comprising F, Cl, Br, I, C₁₋₆alkyl, and phenyl; preferably R⁵³ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵⁴ is selected from the group comprising halogen, C₁₋₈alkyl, and aryl; preferably R⁵⁴ is selected from the group comprising halogen, C₁₋₆alkyl, and aryl; preferably R⁵⁴ is selected from the group comprising halogen, C₁₋₄alkyl, and aryl; preferably R⁵⁴ is selected from the group comprising F, Cl, Br, I, C₁₋₆alkyl, and phenyl; preferably R⁵⁴ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵⁵ is selected from the group comprising halogen, C₁₋₈alkyl, and aryl; preferably R⁵⁵ is selected from the group comprising halogen, C₁₋₆alkyl, and aryl; preferably R⁵⁵ is selected from the group comprising halogen, C₁₋₄alkyl, and aryl; preferably R⁵⁵ is selected from the group comprising F, Cl, Br, I, C₁₋₆alkyl, and phenyl; preferably R⁵⁵ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl.

As used herein, a boride reactant is a reagent that when put into contact with the deposition precursor can produce a metal boride.

Suitable examples of borazines are compounds such as borazine, trichloroborazine, tribromoborazine, and 1,3,5-trimethylborazine.

Suitable examples of boranes are compounds selected from the group consisting of BH₃, B₂H₆, B₁₀H₁₄, B(CH₃)₃, B(CH₂CH₃)₃, B(OCH₃)₃, B[N(CH₃)₂]₃, pinacolborane, and compounds of formula R²⁹BH₃, wherein
R²⁹ is selected from the group comprising NH₃, mono-C₁₋₆alkylamino, di-C₁₋₆alkylamino, tri-C₁₋₆alkylamino, —S(C₁₋₆alkyl)₂, heterocyclyl, heteroalkyl, and heteroaryl substituted with C₁₋₄alkyl; preferably R²⁹ is selected from the group comprising NH₃, mono-C₁₋₄alkylamino, di-C₁₋₄ alkylamino, tri-C₁₋₄alkylamino, —S(C₁₋₄alkyl)₂, heterocyclyl, heteroalkyl, and heteroaryl substituted with C₁₋₄alkyl; preferably R²⁹ is selected from the group comprising NH₃, trimethylamine, triethylamine, dimethylamine, diethylamine, di-tert-butylamine, methylamine, ethylamine, tert-butylamine, tetrahydrofuran, pyridine, and 2-picoline.

Further non-limiting examples of suitable boranes include: BH₃[S(CH₃)₂], ammonia-borane, trimethylamine-borane, triethylamine-borane, pyridine-borane, dimethylamine-borane, 2-picoline-borane, tert-butylamine-borane, and tetrahydrofuran-borane.

In some embodiments, the reactant is a reducing agent, wherein the reducing agent is selected from the group comprising H₂, H₂ plasma, N₂/H₂ plasma, N₂H₄, hydrazines, formic acid, formalin, boranes, SiH₄, Si₂H₆, H₂Si(SiH₃)₂, silanes, and cyclic dienes.

Suitable examples of hydrazines are compounds of formula

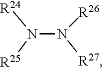

wherein
R²⁴ is selected from the group comprising H, C₁₋₈alkyl, and aryl; preferably R²⁴ is selected from the group comprising H, C₁₋₆alkyl, and aryl; preferably R²⁴ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R²⁵ is selected from the group comprising H, C₁₋₈alkyl, and aryl; preferably R²⁵ is selected from the group comprising H, C₁₋₆alkyl, and aryl; preferably R²⁵ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R²⁶ is selected from the group comprising H, C₁₋₈alkyl, and aryl; preferably R²⁶ is selected from the group comprising H, C₁₋₆alkyl, and aryl; preferably R²⁶ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R²⁷ is selected from the group comprising H, C₁₋₈alkyl, and aryl; preferably R²⁷ is selected from the group comprising H, C₁₋₆alkyl, and aryl; preferably R²⁷ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl.

Suitable examples of boranes are compounds selected from the group consisting of BH₃, B₂H₆, B₁₀H₁₄, B(CH₃)₃, B(CH₂CH₃)₃, B(OCH₃)₃, B[N(CH₃)₂]₃, pinacolborane, and compounds of formula R²⁹BH₃, wherein
R²⁹ is selected from the group comprising NH₃, mono-C₁₋₆alkylamino, di-C₁₋₆alkylamino, tri-C₁₋₆alkylamino, —S(C₁₋₆alkyl)₂, heterocyclyl, heteroalkyl, and heteroaryl substituted with C₁₋₄alkyl; preferably R²⁹ is selected from the group comprising NH₃, mono-C₁₋₄alkylamino, di-C₁₋₄ alkylamino, tri-C₁₋₄alkylamino, —S(C₁₋₄alkyl)₂, heterocyclyl, heteroalkyl, and heteroaryl substituted with C₁₋₄alkyl; preferably R²⁹ is selected from the group comprising NH₃, trimethylamine, triethylamine, dimethylamine, diethylamine, di-tert-butylamine, methylamine, ethylamine, tert-butylamine, tetrahydrofuran, pyridine, and 2-picoline.

Further non-limiting examples of suitable boranes include: BH₃[S(CH₃)₂], ammonia-borane, trimethylamine-borane, triethylamine-borane, pyridine-borane, dimethylamine-borane, 2-picoline-borane, tert-butylamine-borane, and tetrahydrofuran-borane.

Suitable examples of silanes are compounds of formula

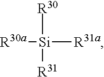

wherein
R³⁰ is selected from the group comprising H, halogen, C₁₋₆alkyl, mono-C₁₋₆alkylamino, di-C₁₋₆ alkylamino, and SiH₃; preferably R³⁰ is selected from the group comprising H, halogen, C₁₋₄alkyl mono-C₁₋₄alkylamino, di-C₁₋₄alkylamino, and SiH₃; preferably R³⁰ is selected from the group comprising H, F, Cl, Br, I, dimethylamino, diethylamino, diisopropylamino, di-tert-butylamino, methylamino, ethylamino, tert-butylamino, di-sec-butylamino, and SiH₃;
R^{30a} is selected from the group comprising H, halogen, C₁₋₆alkyl, mono-C₁₋₆alkylamino, di-C₁₋₆ alkylamino, tri-C₁₋₆alkylamino and SiH₃; preferably R^{30a} is selected from the group comprising H, halogen, C₁₋₄alkyl mono-C₁₋₄alkylamino, di-C₁₋₄alkylamino, tri-C₁₋₄alkylamino and SiH₃; preferably R^{30a} is selected from the group comprising H, F, Cl, Br, I, dimethylamino, diethylamino, diisopropylamino, di-tert-butylamino, methylamino, ethylamino tert-butylamino, di-sec-butylamino, and SiH₃;
R³¹ is selected from the group comprising H, halogen, C₁₋₆alkyl, mono-C₁₋₆alkylamino, di-C₁₋₆ alkylamino, tri-C₁₋₆alkylamino and SiH₃; preferably R³¹ is selected from the group comprising H, halogen, C₁₋₄alkyl mono-C₁₋₄alkylamino, di-C₁₋₄alkylamino, tri-C₁₋₄alkylamino and SiH₃; preferably R³¹ is selected from the group comprising H, F, Cl, Br, I, dimethylamino, diethylamino, diisopropylamino, di-tert-butylamino, methylamino, ethylamino, tert-butylamino di-sec-butylamino and SiH₃;
R^{31a} is selected from the group comprising H, halogen, C₁₋₆alkyl, mono-C₁₋₆alkylamino, di-C₁₋₆alkylamino, tri-C₁₋₆alkylamino and SiH₃; preferably R^{31a} is selected from the group comprising H, halogen, C₁₋₄alkyl mono-C₁₋₄alkylamino, di-C₁₋₄alkylamino, tri-C₁₋₄alkylamino and SiH₃; preferably R^{31a} is selected from the group comprising H, F, Cl, Br, I, dimethylamino, diethylamino, diisopropylamino, di-tert-butylamino, methylamino, ethylamino, tert-butylamino, di-sec-butylamino and SiH₃.

In some embodiments, at least two of R³⁰, R^{30a}, R³¹, or R^{31a} are H.

Suitable examples of silanes are compounds of formula SiₓH_{y}, wherein x is an integer selected from 1, 2, 3, 4, 5, or 6 and y is an integer selected from 0, 2x+2 or 2x. The skilled man in the art will appreciate that a silane of formula SiₓH_{y} includes, straight, branched and cyclic silanes.

Further non-limiting examples of suitable silanes include: bis(diethylamino)silane, diisopropylaminosilane, silane, disilane, trisilane, cyclohexasilane, neopentasilane, di-sec-butylaminosilane.

As used herein the term “cyclic diene” refers to a cyclic group having two double bonds, comprising from 3 to 12 carbon atoms, preferably from 3 to 9 carbon atoms, more preferably from 3 to 7 carbon atoms; more preferably from 3 to 6 carbon atoms; and which may have at least one heteroatom selected from N, O and S, preferably at least one N atom. Cyclic dienes according to the invention may be substituted with one or more substituents selected from the group comprising C₁₋₆alkyl, halogen, C₁₋₆alkoxy, C₁₋₆alkylamino, di-C₁₋₆alkylamino, phenyl, and tri-C₁₋₆alkylsilyl. Further non-limiting examples of suitable cyclic dienes include: 1,3-cyclohexadiene, 1,4-cyclohexadiene, 1-methyl-1,4-cyclohexadiene, 1-methyl-1,3-cyclohexadiene, 2-methyl-1,3-cyclohexadiene, 3,6-bis(trimethylsilyl)-1,4-cyclohexadiene, 1-methyl-3,6-bis(trimethylsilyl)-1,4-cyclohexadiene, 9,10-dihydroanthracene, and 1,4-dihydro-1,4-bis(trimethylsilyl)pyrazine.

In some embodiments the reactant is a sulfide reactant, wherein the sulfide reactant is selected from the group comprising H₂S, S₈, S₂Cl₂, thiols, dithiols, bis(trimethylsilyl)sulfide, CS₂ and disulfides.

As used herein, a sulfide reactant is a reagent that when put into contact with the deposition precursor can produce a metal sulfide.

Suitable examples of thiols include compounds of formula R⁴⁷SH, wherein R⁴⁷ is selected from C₁₋₈alkyl, and aryl; preferably R⁴⁷ is selected from C₁₋₆alkyl, and aryl; preferably R⁴⁷ is selected from methyl, ethyl, n-propyl, iso-propyl, tert-butyl, n-butyl, iso-butyl, sec-butyl, n-pentyl, tert-pentyl, iso-pentyl, phenyl, and naphthyl.

Further non-limiting examples of suitable thiols include: tert-butyl thiol, 1-hexanethiol, tert-pentyl thiol, and thiophenol.

As used herein the term “dithiol” refers to a C₁₋₈alkyl group wherein two hydrogen atoms are replaced with thiol (—SH) group; preferably C₁₋₆alkyl group; preferably a C₁₋₄alkyl group. Further non-limiting examples of suitable dithiols include: 1,2-ethanedithiol, 1,3-propanedithiol, and 1,4-butanedithiol.

Suitable examples of disulfides include compounds of formula R⁴⁷—S—S—R⁴⁸, wherein R⁴⁷ is selected from C₁₋₈alkyl, and aryl; preferably each R⁴⁷ is selected from C₁₋₆alkyl and aryl; preferably R⁴⁷ is selected from methyl, ethyl, n-propyl, iso-propyl, tert-butyl, n-butyl, iso-butyl, sec-butyl, n-pentyl, tert-pentyl, iso-pentyl, phenyl, and naphthyl; R⁴⁸ is selected from C₁₋₈alkyl, and aryl; preferably each R⁴⁸ is selected from C₁₋₆alkyl and aryl; preferably R⁴⁸ is selected from methyl, ethyl, n-propyl, iso-propyl, tert-butyl, n-butyl, iso-butyl, sec-butyl, n-pentyl, tert-pentyl, iso-pentyl, phenyl, and naphthyl.

Further non-limiting examples of suitable disulfides include dimethyl disulfide, diethyl disulfide, and di-tert-butyl disulfide.

In some embodiments, a cycle, and optionally each cycle, of the method as disclosed herein may further comprise a dopant pulse, wherein at least a part of the layer is contacted with one or more dopant(s), by introducing the dopant in the reaction chamber. In other words, the layer deposited in a cycle of the present method may be doped with one or more dopant(s). In some embodiments, the dopant is phosphorous.

In some embodiments, the temperature-controlled vessel is configured for heating the composition, and optional reactants. In some embodiments, the temperature-controlled vessel is maintained at a temperature of at least −50° C. to at most 20° C., or at a temperature of at least 20° C. to at most 250° C., or at a temperature of at least 100° C. to at most 200° C.

In particular embodiments, the apparatus as disclosed herein may be configured to manufacture a semiconductor device as disclosed herein.

In particular embodiments, the apparatus as disclosed herein is configured for forming at least a portion of a semiconductor device as disclosed herein.

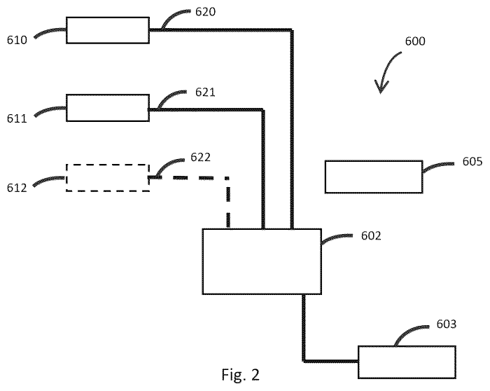

FIG. 2. schematically illustrates an apparatus (600) in accordance with yet additional exemplary embodiments of the disclosure. The apparatus (600) can be used to perform a method as described herein and/or form a (portion of) a transistor or semiconductor device as described herein.

In the illustrated example, the apparatus (600) includes one or more reaction chambers (602), a deposition precursor source (610), a purge gas source (611), optionally one or more reactant sources (612), an exhaust (603), and a controller (605). The deposition precursor source (610) is configured for delivering one or more compositions comprising one or more deposition precursors as described herein (e.g. gas) into the reaction chamber (602). The reaction chamber (602) can include any suitable reaction chamber, such as an ALD or CVD reaction chamber.

The deposition precursor source (610) may include a vapor delivery vessel. In the vapor delivery vessel (610), the composition comprising the precursor may be alone or mixed with one or more carrier (e.g., inert) gases. The one or more optional reactant sources (612) can include a vessel and one or more reactants as described herein-alone or mixed with one or more carrier (e.g., inert) gases. The purge gas source (611) can include one or more inert gases such as N₂ or a noble gas, as described herein. The apparatus (600) can include any suitable number of gas sources. The gas sources (610)-(612) can be coupled to reaction chamber (602) via respective lines (620)-(622), which can each include flow controllers, valves, heaters, and the like. The exhaust (603) can include one or more vacuum pumps.

The controller (605) includes electronic circuitry and software to selectively operate valves, manifolds, heaters, pumps, and other components included in the apparatus (600). Such circuitry and components operate to introduce the composition, optional reactants, and purge gases from the respective sources (610)-(612). The controller (605) can control timing of gas pulse sequences, temperature of the substrate and/or reaction chamber, pressure within the reaction chamber, and various other operations to provide proper operation of the apparatus (600). The controller (605) can include control software to electrically or pneumatically control valves to control flow of precursors, optional reactants and purge gases into and out of the reaction chamber (602). The controller (605) can include modules such as a software or hardware component, e.g., a FPGA or ASIC, which performs certain tasks. A module can advantageously be configured to reside on the addressable storage medium of the control system and be configured to execute one or more processes.

Other configurations of the apparatus (600) are possible, including different numbers and kinds of compositions and optional reactant sources, and purge gas sources. Further, it will be appreciated that there are many arrangements of valves, conduits, composition sources, optional reactant sources, and purge gas sources that may be used to accomplish the goal of selectively feeding gases into the reaction chamber (602). Further, as a schematic representation of an apparatus, many components have been omitted for simplicity of illustration, and such components may include, for example, various valves, manifolds, purifiers, heaters, containers, vents, and/or bypasses.

In addition, embodiments of the controller may include a combination of hardware, software, and electronic components or modules that, for purposes of discussion, may be portrayed as if primarily implemented in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits.

During operation of the reactor apparatus (600), substrates, such as semiconductor wafers (not illustrated), are transferred from, e.g., a substrate handling system to reaction chamber (602). Once substrate(s) are transferred to the reaction chamber (602), one or more gases from the gas sources (610)-(612), such as composition, carrier gases, optional reactants, and/or purge gases, are introduced into reaction chamber (602) via the respective lines (620)-(622).

Another aspect of the present disclosure relates to a method for forming a layer on a semiconductor substrate, comprising the steps of:
a) providing a semiconductor substrate into a reaction chamber;
b) executing one or more cycles, each cycle comprising:
   a deposition precursor pulse, wherein at least a part of the semiconductor substrate is contacted by a vapor of a composition comprising the deposition precursor by introducing the vapor of the deposition precursor into the reaction chamber;
      wherein the deposition precursor comprises:
      a metal (M); and
      at least one phosphinimide ligand (L¹);
         whereby, as a result of the cycles, the layer is formed on the semiconductor substrate in the reaction chamber.

In some embodiments, the at least one phosphinimide ligand (L¹) has a structure according to formula (I):

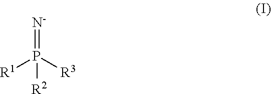

wherein,
R¹ is selected from the group comprising H, a hydrocarbyl group, amino group and a silyl group;
R² is selected from the group comprising H, a hydrocarbyl group, amino group and a silyl group;
R³ is selected from the group comprising H, a hydrocarbyl group, an amino group and a silyl group; with the proviso that at least one of R¹, R², and R³ is not H.

Further embodiments of the phosphinimide ligand (L¹) having a structure according to formula (I) have been described hereinabove.

In accordance with step b) of the present method, and after providing the substrate to the reaction chamber, one or more (deposition) cycles are executed to form the layer on the semiconductor substrate.

In particular, the present (deposition) method may be a cyclical deposition process, preferably a combination of cyclical deposition processes, such as an atomic layer deposition (ALD) process or a cyclical chemical vapor deposition (CVD) process. Each cyclical deposition process comprises one or more distinct (deposition) cycles. In particular embodiments, the method as disclosed herein may be an ALD method. In contrast to sputtering techniques commonly used within the state of the art for deposition of thin films and layers for the manufacturing of various semiconductors and transistors, cyclical deposition processes such as ALD were found to provide more uniform deposition across the surface of the substrate and/or (previously) deposited layers.

As used herein, the synonymous terms “deposition” or “cyclic deposition” or “cyclic deposition process” or “cyclical deposition process” refer to a sequential introduction of precursors (and/or reactants) into a reaction chamber to deposit a layer or film over a substrate and includes processing techniques such as ALD, CVD, and hybrid cyclical deposition processes that include an ALD component and a CVD component. Typically, one deposition cycle may form a film or layer ranging from about 0.01 nm to about 0.2 nm in an ALD process, or from about 0.01 nm to about 2.0 nm or more in a cyclic CVD process. However, the experimental thickness may vary depending on the amount and type of cycles and available reaction sites on the substrate and/or a previously deposited layer.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

In ALD processes, during each cycle, generally a precursor (e.g. a deposition precursor) is introduced to a reaction chamber and is chemisorbed to a deposition surface (e.g., a substrate surface that can include a previously deposited material from a previous ALD cycle or other material), thereby forming a material, e.g. about a monolayer or sub-monolayer of material, or several monolayers of material, or a plurality of monolayers of material, which does not readily react with additional precursor (i.e., a self-limiting reaction). Thereafter, in some cases, a reactant (e.g., another precursor or reaction gas such as an oxygen reactant) may be introduced into the process chamber. The reactant can be capable of further reaction with the precursor. It should be noted that, as used herein, ALD processes are not necessarily comprised of a sequence of self-limiting surface reactions.

In some embodiments step b) of the method according to the present disclosure further comprises a reactant pulse, wherein at least a part of the semiconductor substrate is contacted by at least one reactant, by introducing the at least one reactant into the reaction chamber. The description of the types of reactants provided under the apparatus section applies mutatis mutandis for the description of the method.

Optionally, purging steps can be utilized during one or more repetitions, e.g. during each deposition step, to remove any excess composition from the process chamber and/or remove any excess reactant and/or reaction byproducts from the reaction chamber.

As used herein, the term “purge” may refer to a procedure in which an inert or substantially inert gas is provided to a reaction chamber in between two pulses of gases that react with each other. For example, a purge, e.g. using an inert gas such as a noble gas, may be provided between subsequent pulses, thus avoiding or at least minimizing gas phase interactions between composition and/or reactant(s).

In particular embodiments, the method as disclosed herein provides that the reaction chamber is purged before and/or after each precursor pulse. In particular embodiments, the method as disclosed herein provides that the reaction chamber is purged before and/or after each deposition precursor pulse and reactant pulse.

In some embodiments, the duration of the purge is greater than or equal to 0.1 seconds; preferably greater than or equal to 0.5 seconds; preferably greater than or equal to 1 second; preferably greater than or equal to 5 seconds; preferably greater than or equal to 10 seconds. In some embodiments, the duration is less than or equal to 60 seconds; preferably less than or equal to 45 seconds; preferably less than or equal to 35 seconds; preferably less than or equal to 20 seconds; preferably less than or equal to 10 seconds. In some embodiments, the duration o is from 0.1 to 60 seconds; preferably from 0.5 to 20 seconds; preferably from 5 to 10 seconds; preferably from 1 to 10 seconds.

Advantageously, a cyclical deposition process as disclosed herein can be a thermal deposition process. In other words, in some embodiments, none of the pulses or purges in the cyclical deposition process employs a plasma. In the case of thermal cyclical deposition processes, a duration of the step of providing the deposition precursor to the reaction chamber, and/or a duration of the step of providing the reactant to the reaction chamber can be relatively long to allow the precursors and/or reactants to react with a surface of the substrate and/or a previously deposited layer.

In some embodiments, the duration of the step of providing the deposition precursor to the reaction chamber is greater than or equal to 0.1 seconds; preferably greater than or equal to 0.5 seconds; preferably greater than or equal to 1 second; preferably greater than or equal to 5 seconds; preferably greater than or equal to 10 seconds. In some embodiments, the duration is less than or equal to 60 seconds; preferably less than or equal to 45 seconds; preferably less than or equal to 35 seconds; preferably less than or equal to 20 seconds; preferably less than or equal to 10 seconds. In some embodiments, the duration is from 0.1 to 60 seconds; preferably from 0.5 to 20 seconds; preferably from 5 to 10 seconds; preferably from 1 to 10 seconds.

In some embodiments, the duration of the step of providing the reactant to the reaction chamber is greater than or equal to 0.1 seconds; preferably greater than or equal to 0.5 seconds; preferably greater than or equal to 1 second; preferably greater than or equal to 5 seconds; preferably greater than or equal to 10 seconds. In some embodiments, the duration is less than or equal to 60 seconds; preferably less than or equal to 45 seconds; preferably less than or equal to 35 seconds; preferably less than or equal to 20 seconds; preferably less than or equal to 10 seconds. In some embodiments, the duration is from 0.1 to 60 seconds; preferably from 0.5 to 20 seconds; preferably from 5 to 10 seconds; preferably from 1 to 10 seconds.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical deposition process may comprise generating a plasma in the reaction chamber.

In some embodiments, the method as disclosed herein may be a continuous vacuum deposition process. In the context of a continuous vacuum deposition process, a material is deposited onto a substrate in a reaction chamber without the introduction of atmospheric air or any interruptions that would break the controlled vacuum environment. This process involves maintaining a consistent vacuum pressure within the reaction chamber.

In particular embodiments, the method as disclosed herein provides that the layer may be formed without any intervening vacuum break. The term “without any intervening vacuum break” can refer to without breaking a vacuum, without interruption as a timeline, without any material intervening step, without changing treatment conditions, and/or immediately thereafter.

In particular embodiments, the formation of the layer may comprise at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 5000 cycles; preferably from at least 1 cycle to at most 1000 cycles; preferably from at least 2 cycles to at most 100 cycles, preferably from at least 5 cycles to at most 50 cycles.

Each cycle may comprise one or more pulses. In some embodiments, at least one pulse involves a self-limiting surface reaction. In some embodiments, all pulses involve a self-limiting surface reaction. In the context of ALD, a self-limiting surface reaction refers to a chemical reaction that automatically halts or slows down once a certain threshold or coverage is reached on a surface, for instance, once a complete monolayer or sub-monolayer is formed the reactions stops by preventing further reaction with additional precursor. In some embodiments, a cycle comprises one or more precursor pulse(s), optionally one or more reactant pulse(s).

In particular embodiments, the layer may have an average thickness of between 10.0 nm and 100.0 nm, or between 1.0 nm and 100.0 nm, or between 5.0 nm and 20 nm, or between 1.0 and 10.0 nm, or between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm. In particular embodiments, the method as disclosed herein provides that the channel layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In some embodiments, a cycle to grow a layer may comprise the following sequence of pulses: a deposition precursor pulse, and an optional reactant pulse. In the deposition precursor pulse one or more deposition precursor(s) is provided into the reaction chamber and may chemisorb to the substrate (i.e., adheres and forms chemical bonds with atoms or molecules on the surface of said substrate and/or a previously deposited layer or material). In the optional reactant pulse, one or more reactant(s) is provided into the reaction chamber and may react with the chemisorbed metal to form a layer on at least a part of the substrate. The number of cycles determines the overall thickness of the deposited layer.

An advantage of the presently disclosed cyclical deposition process(es) is the precise control over the overall layer thickness.

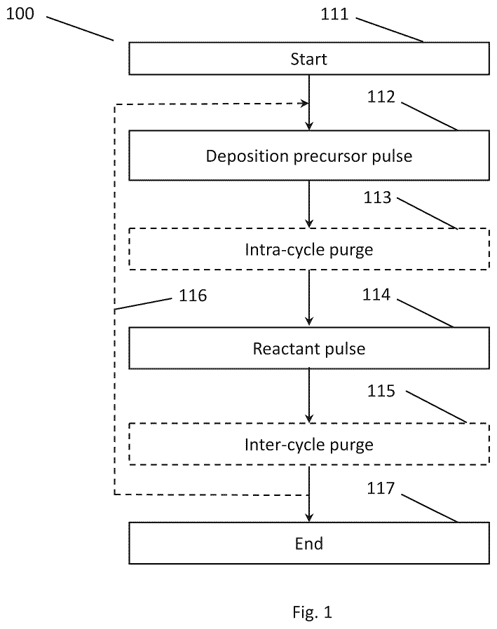

FIG. 1. schematically illustrates an exemplary embodiment of the method (100) for forming a layer on a semiconductor substrate as disclosed herein. The method starts (111) after a substrate has been provided to a reaction chamber. The cyclical deposition process comprises providing one or more compositions comprising at least one deposition precursor as described herein (e.g., gas) into the reaction chamber in a deposition precursor pulse (112). Optionally, the reaction chamber is purged (113) after the deposition precursor pulse (112). The deposition precursor pulse is configured for delivering the composition comprising the deposition precursor as described herein. Optionally, one or more reactants are provided to the reaction chamber in a reactant pulse (114). Optionally, the reaction chamber can be purged (115) after the reactant pulse.

The deposition precursor pulse (112), the optional reactant pulse (114), and the optional purge steps (113, 115) can be repeated (116) any number of times, either sequentially or individually, until the layer reaches a desired thickness. Once the desired thickness is achieved, the method concludes (117). Following this, the substrate can be subjected to further processing steps, as known in the art, to fabricate a device structure and/or complete the device as described herein.

It should be appreciated that the deposition precursor pulse (112) and the optional reactant pulse (114) may overlap in a cycle. Further, the sequence of each method step (112 to 115) within each cycle may vary. For instance, and in another exemplary embodiment, a cycle may comprise the consecutive steps of an optional reactant pulse and a deposition precursor pulse. Hence, an optional reactant pulse may precede a deposition precursor pulse.

In particular embodiments, the method as disclosed herein provides that the deposition precursor pulse and the optional reactant pulse comprise a plurality of micro pulses. A “micro pulse” as used herein is a short period during which one or more deposition precursor(s) and optionally one or more reactant(s), may be introduced into the reaction chamber. Hence, the method as disclosed herein provides high flexibility in pulse sequence and length, thereby providing a cost-effective and more efficient method compared to conventional layer production processes comprised in the art.

In some embodiments, the deposition precursor pulse, and optionally one or more reactant(s) may last from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

It shall be understood that any two steps and/or pulses and/or micro pulses can be separated by a purge. Thus, in some embodiments, a deposition precursor pulse and optionally a reactant pulse, may be separated by a purge. In some embodiments, subsequent cycles are separated by a purge.

In particular embodiments, the reaction chamber may be purged before and/or after a deposition precursor pulse, and an optional reactant pulse. An advantage of purging is to prevent gas phase reactions that would prevent/eliminate self-limiting surface reactions. Another advantage of purging the reaction chamber before and/or after each precursor pulse and/or optional reactant pulse is that any residual precursor, reactant and/or reaction byproduct is removed, thereby avoiding cross-contamination between pulses and resulting in films or layers with high purity and less detrimental defects.

The method as disclosed herein may be performed at different temperatures and/or pressures. In particular embodiments, the method as disclosed herein provides that the substrate may be heated to a temperature of about 80° C. to about 500° C., or about, or about 80° C. to about 400° C., or about 100° C. to about 400° C., or about 125° C. to about 400° C., preferably about 150° C. to about 400° C., or about 175° C. to about 400° C., preferably about 200° C. to about 400° C., or about 200° C. to about 300° C., or about 250° C. to about 400° C., or about 300° C. to about 400° C. The listed temperatures can decrease the time needed for material deposition, although lower or higher temperatures can be considered still.

In particular embodiments, the method as disclosed herein provides that the pressure in the reaction chamber is between about 0.1 Torr and about 100.0 Torr, or between about 0.5 Torr and about 100.0 Torr, or between about 1.0 Torr and about 100.0 Torr, or between about 2.0 Torr and about 100.0 Torr, or between about 5.0 Torr and about 100.0 Torr, or between about 5.0 Torr and about 80.0 Torr, or preferably between about 5.0 Torr and about 50.0 Torr, or between about 10.0 Torr and about 50.0 Torr, or between 0.5 and about 10.0 Torr. The listed pressures can decrease the time needed for material deposition, although lower or higher pressures can be considered still.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the composition comprising the deposition precursor, the optional one or more reactant, is provided to the reaction chamber by means of a carrier gas. Exemplary carrier gases include nitrogen (N₂) and a noble gas such as He, Ne, Ar, Xe, or Kr.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

Another aspect of the present disclosure relates to a semiconductor device structure formed according to the method described herein. The semiconductor device structure preferably comprises a layer comprising a plurality of metal atoms selected from the group comprising Al, Ga, In, a lanthanide, a transition metal and a metalloid. Preferably the metal is selected from the group comprising Al, Ga, In, Si, Ge, B, a rare earth metal, a group 4 metal, a group 5 metal, and a group 6 metal.

In some embodiments the semiconductor device structure comprises a layer comprising at least one phosphinimide ligand (L¹) having a structure according to formula (I):

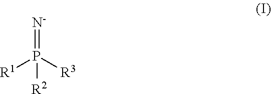

wherein,
R¹ is selected from the group comprising H, a hydrocarbyl group, amino group and a silyl group;
R² is selected from the group comprising H, a hydrocarbyl group, amino group and a silyl group;
R³ is selected from the group comprising H, a hydrocarbyl group, an amino group and a silyl group; with the proviso that at least one of R¹, R², and R³ is not H.

Yet another aspect of the present invention refers to a layer positioned on a surface of a semiconductor substrate, comprising a metal selected from the group comprising Al, Ga, In, a lanthanide, a transition metal and a metalloid, wherein said layer is formed by the method described herein. Preferably the metal is selected from the group comprising Al, Ga, In, Si, Ge, B, a rare earth metal, a group 4 metal, a group 5 metal, and a group 6 metal.

The subject matter of the present disclosure includes all novel and nonobvious combinations and subcombinations of the various processes, apparatus, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the apparatus may not be described in detail. Furthermore, the connecting lines shown in the various figures are intended to represent exemplary functional relationships and/or physical couplings between the various elements. Many alternative or additional functional relationships or physical connections may be present in the practical apparatus, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. A composition for forming a layer on a semiconductor substrate, the composition comprising
a deposition precursor comprising:
a central atom or ion (M); and
at least one phosphinimide ligand (L¹).

2. The composition according to claim 1, wherein the at least one phosphinimide ligand (L¹) has a structure according to formula (I): 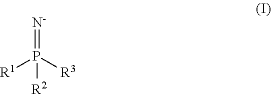
wherein,
R¹ is selected from the group comprising H, an optionally substituted hydrocarbyl group, optionally substituted amino group, and an optionally substituted silyl group;
R² is selected from the group comprising H, an optionally substituted hydrocarbyl group, optionally substituted amino group, and an optionally substituted silyl group;
R³ is selected from the group comprising H, an optionally substituted hydrocarbyl group, an optionally substituted amino group, and an optionally substituted silyl group;
with the proviso that at least one of R¹, R², and R³ is not H.

3. The composition according to claim 2, wherein
R¹ is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, tri-C₁₋₆alkylsilyl;
R² is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, and tri-C₁₋₆alkylsilyl;
R³ is selected from the group comprising H, C₁₋₁₀alkyl, C₂₋₁₀alkenyl, C₂₋₁₀alkynyl, C₃₋₁₀cycloalkyl, aryl, aryl substituted with C₁₋₆alkyl or trimethylsilyl, —NH₂, mono-C₁₋₆alkylamino, di-C₁₋₆alkylamino, —SiH₃, mono-C₁₋₆alkylsilyl, di-C₁₋₆alkylsilyl, and tri-C₁₋₆alkylsilyl.

4. The composition according to claim 2, wherein each of R¹, R², and R³ is independently selected from C₁₋₁₀alkyl.

5. The composition according to claim 1, wherein the central atom or ion is selected from the group comprising Al, Ga, In, Si, Ge, B, a rare earth metal, a group 4 metal, a group 5 metal, and a group 6 metal.

6. The composition according to claim 1, wherein the deposition precursor comprises a structure according to M(L¹)₄, wherein M is selected from the group comprising a group 4 metal, V, and Mo.

7. The composition according to claim 1, wherein the deposition precursor comprises a structure according to M(L¹)₃ or a dimer thereof, wherein M is selected from the group comprising Al, In, Ga, and a rare earth metal.

8. The composition according to claim 1, wherein the deposition precursor further comprises at least one further ligand (L²), wherein said further ligand (L²) is selected from the group consisting of cyclopentadienyl ligands, amidinate ligands, amidate ligands, alkyl ligands, alkylamido ligands, imido ligands, alkoxide ligands, siloxy ligands, oxo ligands, hydrido ligands, halide ligands, 1-4-diazabutadiene ligands, guanidinate ligands, and diketonate ligands.

9. The composition according to claim 8, wherein the deposition precursor comprises a structure according to M(L¹)ₓ(L²)_{y}, wherein:
x is an integer selected from 1, 2, or 3;
y is an integer selected from 1, 2, or 3;
wherein x+y is equal to 4; and
M is selected from the group comprising a group 4 metal, V, or Mo.

10. The composition according to claim 8, wherein the deposition precursor comprises a structure according to M(L¹)ₓ(L²)_{y}, wherein:
x is an integer selected from 1, 2, 3, or 4;
y is an integer selected from 1, 2, 3, or 4;
wherein x+y is equal to 2, 3, 4, 5, 6, 7, or 8; and
M is selected from the group comprising a group 4 metal, a group 5 metal, or a group 6 metal.

11. The composition according to claim 8, wherein the deposition precursor comprises a structure according to: M(L¹)(L²)₂ or a dimer thereof, wherein:
M is selected from the group comprising Al, In, Ga, and a rare earth metal.

12. The composition according to claim 1, wherein the deposition precursor comprises a structure according to: M(L¹)ₓ(O)_{y}, wherein:
(i) M is a group 5 metal, x=3 and y=1; or
(ii) M is a group 6 metal, x=2 and y=2.

13. The composition according to claim 1, wherein the deposition precursor comprises a structure according to: M(L¹)ₓ(NR¹³)_{y}, wherein:
R¹³ is selected from the group comprising C₁₋₈alkyl, —SiH₃, mono-C₁₋₈alkylsilyl, di-C₁₋₈alkylsilyl, and tri-C₁₋₈alkylsilyl;
(i) M is a group 5 metal, x=3 and y=1; or
(ii) M is a group 6 metal, x=2 and y=2.

14. The composition according to claim 1, wherein the deposition precursor has a purity of at least 95.0% (by weight).

15. A vapor delivery vessel comprising the composition according to claim 1, wherein the vapor delivery vessel is constructed and arranged to supply a vapor of the deposition precursor to a reaction chamber of a vapor deposition apparatus.

16. A vapor deposition apparatus comprising:
a reaction chamber constructed and arranged to hold at least a semiconductor substrate;
a vapor delivery vessel comprising a composition comprising a deposition precursor, wherein the vapor delivery vessel is constructed and arranged to provide a vapor of the deposition precursor;
a precursor distribution and removal system configured to provide the vapor of the deposition precursor from the vapor delivery vessel to the reaction chamber and to remove the vapor of the deposition precursor from the reaction chamber; and
a sequence controller operably connected to the precursor distribution system and removal system, and comprising a memory provided with a program configured to control the flow of the composition comprising the deposition precursor from the vapor delivery vessel to the reaction chamber by activating the precursor distribution and removal system during one or more cycles; whereby, as a result of the cycles, a layer is formed on the semiconductor substrate in the reaction chamber;
wherein the deposition precursor comprises:
a central atom or ion (M); and
at least one phosphinimide ligand (L¹).

17. The apparatus according to claim 16, wherein the at least one phosphinimide ligand (L¹) has a structure according to formula (I): 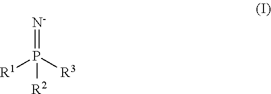
wherein,
R¹ is selected from the group comprising H, an optionally substituted hydrocarbyl group, optionally substituted amino group, and an optionally substituted silyl group;
R² is selected from the group comprising H, an optionally substituted hydrocarbyl group, optionally substituted amino group, and an optionally substituted silyl group;
R³ is selected from the group comprising H, an optionally substituted hydrocarbyl group, an optionally substituted amino group, and an optionally substituted silyl group;
with the proviso that at least one of R¹, R², and R³ is not H.

18. A method for forming a layer on a semiconductor substrate, comprising the steps of:
a) providing a semiconductor substrate into a reaction chamber;
b) executing one or more cycles, each cycle comprising:
a deposition precursor pulse, wherein at least a part of the semiconductor substrate is contacted by a vapor of a composition comprising the deposition precursor by introducing the vapor of the deposition precursor into the reaction chamber;
wherein the deposition precursor comprises:
a central atom or ion (M); and
at least one phosphinimide ligand (L¹);
whereby, as a result of the cycles, the layer is formed on the semiconductor substrate in the reaction chamber.

19. The method according to claim 18, wherein the at least one phosphinimide ligand (Li) has a structure according to formula (I): 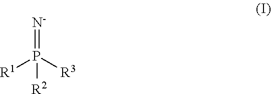
wherein,
R¹ is selected from the group comprising H, an optionally substituted hydrocarbyl group, optionally substituted amino group, and an optionally substituted silyl group;
R² is selected from the group comprising H, an optionally substituted hydrocarbyl group, optionally substituted amino group, and an optionally substituted silyl group;
R³ is selected from the group comprising H, an optionally substituted hydrocarbyl group, an optionally substituted amino group, and an optionally substituted silyl group;
with the proviso that at least one of R¹, R², and R³ is not H.

20. The method according to claim 18, wherein the method comprises an atomic layer deposition (ALD) process or a cyclical chemical vapor deposition (CVD) process.
